(19) United States
(12) Patent Application Publication
(10) Pub. No.: US 2026/0349006 A1
(43) Pub. Date: Nov. 5, 2026

(54) PROBE HEAD WITH IMPROVED CONTACT PROBES

(71) Applicant: TECHNOPROBE S.P.A., Cernusco Lombardone (LC) (IT)

(72) Inventors: Raffaele VALLAURI, Cernusco Lombardone (LC) (IT); Nadia PADERNO, Cernusco Lombardone (LC) (IT); Camilla CAMARRI, Cernusco Lombardone (LC) (IT); Giulia STUCCHI, Cernusco Lombardone (LC) (IT); Stefano FELICI, Cernusco Lombardone (LC) (IT); Fabio MORGANA, Cernusco Lombardone (LC) (IT); Roberto CRIPPA, Cernusco Lombardone (LC) (IT); Giuseppe CRIPPA, Cernusco Lombardone (LC) (IT)

(73) Assignee: TECHNOPROBE S.P.A., Cernusco Lombardone (LC) (IT)

(21) Appl. No.: 19/476,830

(22) PCT Filed: Apr. 10, 2024
(86) PCT No.: PCT/EP2024/059755

§ 371 Date: Oct. 21, 2025

(30) Foreign Application Priority Data
Apr. 26, 2023 (IT) 102023000008088

(51) Int. Cl. G01R 1/067; G01R 31/26

(52) U.S. Cl. CPC G01R 1/06722; G01R 1/06755; G01R 1/06772; G01R 31/26

(57) ABSTRACT

A probe head for the testing of electronic devices is described having a contact probe that includes a body which extends along a longitudinal axis between first and second ends adapted to contact respective contact pads, and a guide having a guide hole configured for housing at least a portion of the contact probe. The contact probe includes an intermediate section arranged between the first and second ends which is elastically compliant at least along the longitudinal axis.

### FIELD OF APPLICATION

The present invention relates to a probe head adapted to perform the testing of electronic devices integrated on a semiconductor wafer, for instance high-frequency devices. The following description is made with reference to this field of application with the only purpose of simplifying the exposition thereof.

### PRIOR ART

As it is well known, a probe head is essentially a device adapted to electrically contact a plurality of contact pads or pads of a microstructure, particularly an electronic device integrated on a semiconductor wafer, with corresponding channels of a testing apparatus which performs the functionality testing thereof.

The testing performed on integrated circuits is in particular useful for detecting and isolating defective circuits as early as in the production phase. Normally, probe heads are thus used for the testing of the circuits integrated on wafers before cutting and assembling them inside a chip containment package.

A probe head essentially comprises a plurality of contact probes housed in a pair of supports or guides which are substantially plate-like and parallel to each other. These plate-like supports are equipped with proper guide holes and are located at a distance from each other so as to leave a free area or air gap for the movement and the possible deformation of the contact probes, which are normally formed by wires of special alloys with good electrical and mechanical properties.

The contact probes generally extend between a first end portion, intended to contact the pads of the device under test, and a second end portion, intended to contact a space transformer or a printed circuit board (PCB).

The correct operation of a probe head is basically linked to two parameters: the vertical movement (or overtravel or overdrive) of the contact probes and the horizontal movement (or scrub) of the contact tips of these probes on the pads during the contact with the device under test. All these features are to be evaluated and calibrated in the manufacturing step of a probe head, the good electrical connection between the contact probes and the device under test should always be ensured. It is thus particularly important to ensure a proper contact of the contact probes with the various pads during the test.

In general, the maximum overtravel of a contact probe is equal to the dimensions of the probe part projecting with respect to the lower guide, this projecting part returning into the lower guide in case of contact with the device under test due to the bending and deformation of the probe itself. The height of this projecting part is however constrained by the mechanical resistance of the probe and is normally reduced. Moreover, it should be added that the maximum value of the overtravel of the probes can only theoretically be reached, since even with much smaller overtravels problems linked to the interlocking and to the deformation of the probes occur.

In accordance with some known solutions, contact probes having a pre-deformation are manufactured, but these solutions have various drawbacks, such as for instance the difficult maintenance and the need for particular expedients for the retention of the probes, as well as interlocking problems during the test. Another problem of these known solutions is linked to the wear of the contact pads caused by the probes themselves.

Furthermore, very short probes have been manufactured in the past in order to ensure optimum performances also for high-frequency tests, where the length of the probe is a significant problem, in particular due to the self-inductance phenomenon. In this case, however, the reduced length of the body of the probes dramatically increases the rigidity of the probe itself, causing an increase in the force exerted by the respective contact tip on the various pads, which can lead to a breaking of the pads, with irreparable damage of the device under test. The increase in the rigidity of the contact probe due to the reduction in the length of the body thereof also increases the risk of breaking the probes themselves. In this case too, there is thus the need for contact probes which are able to ensure an improved contact during the test.

The technical problem of the present invention is to devise a probe head having such structural and functional features as to allow the limitations and the drawbacks still affecting the known solutions to be overcome; such probe head should, in particular, be able to ensure an optimum contact with the contact pads during the test, for instance with an improved control of the contact force of the probes, while eliminating the risks of interlocking the probes and/or the risks of breaking them.

### SUMMARY OF THE INVENTION

The solution idea underlying the present invention is to manufacture a probe head in which the contact probes are subjected, during the test, to an elastic deformation preferably occurring mainly (but not necessarily) in the longitudinal direction. In particular, the contact probes have at least one elastically compliant intermediate section, so that they substantially act as an elastic spring, where the above elastically compliant intermediate section is structured and sized so as to ensure an optimum contact force and at the same time a proper stability of the contact probes.

Configurations in which the elastically compliant intermediate section is configured to generate a torsion on the pad, or a transversal scrub (generally a lateral movement) are also possible. In fact, some embodiments can provide elastically weaker portions and elastically stronger portions of the elastically compliant intermediate section, as well as helical shapes for this elastically compliant intermediate section.

Based on this solution idea, the above technical problem is solved by a probe head for the testing of electronic devices, comprising at least one contact probe with a body which extends along a longitudinal axis between a first end and a second end, said ends being adapted to contact respective contact pads, and at least one guide with at least one guide hole configured for housing at least one portion of the contact probe, wherein the contact probe comprises at least one intermediate section arranged between the first end and the second end which is elastically compliant (or yielding) at least along said longitudinal axis, and wherein the elastically compliant intermediate section is configured (sized and shaped) to define a contact force (for instance to define an intensity and/or direction) exerted by the contact probe onto the contact pads, said contact probe acting as a spring.

More particularly, the invention comprises the following additional and optional features, taken individually or in case in combination.

According to an aspect of the present invention, the contact probe can have a length which is lower than 2000 μm, preferably lower than 1000 μm, still more preferably equal to or lower than 800 μm, said length being measured along the longitudinal axis.

According to an aspect of the present invention, the guide can comprise a first guide portion and a second guide portion, the second guide portion being initially made structurally independent from the first guide portion and being subsequently associated therewith.

According to an aspect of the present invention, the second guide portion can be superimposed on the first guide portion and be fitted on the contact probe.

According to an aspect of the present invention, the second guide portion can be connected to the first guide portion by attachment means.

According to an aspect of the present invention, the elastically compliant intermediate section can be obtained by interdigitated engravings formed in the body of the contact probe, said interdigitated engravings being configured so that the contact probe acts as an elastic spring.

According to an aspect of the present invention, the elastically compliant intermediate section can be sawtooth-shaped.

According to an aspect of the present invention, the elastically compliant intermediate section can be structured in a plurality of polygonal elastic elements which follow each other along the longitudinal axis of the contact probe, such as for instance a succession of interconnected hexagons.

According to an aspect of the present invention, the elastically compliant intermediate section can be structured in a plurality of oblong-shaped elastic elements which follow each other along the longitudinal axis of the contact probe.

According to an aspect of the present invention, the contact probe can have a non-circular cross section, preferably rectangular, more preferably rectangular with a first side having a length of 30 μm and a second side having a length of 70 μm.

According to an aspect of the present invention, the contact probe can comprise a plurality of elastically compliant intermediate sections separated from each other by portions of the probe body, said elastically compliant intermediate sections following each other along the longitudinal axis of the contact probe.

According to an aspect of the present invention, the elastically compliant intermediate section can be positioned at the guide so as to be at least partially accommodated in the guide hole.

According to an aspect of the present invention, the probe head can comprise a lower guide and an upper guide separated from each other by a gap, the lower guide and the upper guide comprising respective lower guide holes and upper guide holes for housing the contact probes.

According to an aspect of the present invention, the elastically compliant intermediate section can be placed at the gap between the lower guide and the upper guide.

According to an aspect of the present invention, the lower guide holes and the upper guide holes can be unaligned with respect to each other, i.e. the holes related to a same probe are not on a same axis which is parallel to the longitudinal axis of the contact probe, that is a vertical axis.

According to an aspect of the present invention, the elastically compliant intermediate section can extend along the longitudinal axis by a length of 1000 μm to 80 μm.

According to an aspect of the present invention, the elastically compliant intermediate section can extend with a pitch of 100 μm to 5 μm.

According to an aspect of the present invention, the contact probe can be made of a material selected from Pd, PdCo, Ni, NiCo, Au, Pt, Ag, Rh or combinations thereof.

According to an aspect of the present invention, at least one guide hole can comprise at least one wall which is tilted with respect to the longitudinal axis of the contact probe, said guide hole thereby having a non-rectilinear sectional shape.

According to an aspect of the present invention, the guide hole can comprise a pair of tilted opposite walls.

According to an aspect of the present invention, the elastically compliant intermediate section can be configured so that the contact force exerted by the contact probe onto the contact pads is substantially directed along the longitudinal axis of the probe, with substantially null transversal component.

In addition or as an alternative, the contact force can also have a transversal component, or more generally a non-longitudinal component. In other words, according to an aspect of the present invention, the elastically compliant intermediate section can be configured so that the contact force exerted by the contact probe onto the contact pads has both a longitudinal/axial component and a component along an axis which is different from said longitudinal axis, for instance a transversal one, to which a deformation both in the longitudinal direction and with a component along a different direction (for instance transversal, torsional, etc.) thus corresponds.

According to an aspect of the present invention, the elastically compliant intermediate section can comprise an elastically weaker wall of an opposite wall thereof, thereby causing a lateral movement during the overtravel.

According to an aspect of the present invention, the elastically compliant intermediate section can comprise an elastic deformation mechanism (also called further elastic element) comprising arms with a different elasticity (in which for instance an arm can be elastically weaker than the other one), so that the elastic deformation of this section occurs not only in the longitudinal direction but also along other directions, causing for instance a scrub movement of the first end of the contact probe on the pads of the device under test.

According to an aspect of the present invention, the elastically compliant intermediate section can be configured to perform a torsion during the contact with the device under test and thus during the overtravel.

According to an aspect of the present invention, the second end of the contact probe can comprise an arm, which laterally protrudes from the body thereof and is configured to perform the contact with the contact pads of an interface card (such as a PCB for instance), said arm being adapted to offset the contact point between the contact probe and the contact pad of the interface card with respect to the longitudinal axis of the contact probe.

According to an aspect of the present invention, the probe head can comprise a plurality of contact probes which have arms with a different length between each other, the length of these arms being measured along the longitudinal development direction thereof.

According to an aspect of the present invention, the first end of the contact probe can comprise a high-hardness material, such as rhodium for instance.

According to an aspect of the present invention, the probe head can further comprise a conductive portion formed on the guide, said conductive portion including at least one group of said guide holes and being adapted to contact and short-circuit a corresponding group of contact probes housed in said group of holes and intended to carry a given kind of signal, thereby forming a given conductive domain, wherein at least one portion of the contact probe is in contact with said conductive portion.

According to an aspect of the present invention, the elastically compliant intermediate section can be structured as a plurality of interconnected elastic elements which follow each other along the longitudinal axis of the contact probe, each one of said elastic elements being configured to be compressed under the action of the pressure generated during the testing of the device under test. Each one of said elastic elements is also configured to be subjected, during said compression, to a reduction in its dimensions along said longitudinal axis of the contact probe and to an increase in its transversal dimensions (i.e. along an axis which is orthogonal to the above longitudinal axis), said elastic elements having an elongated shape along the longitudinal axis.

According to an aspect of the present invention, at least one of the elastic elements can be configured to contact, through a side wall thereof, the conductive portion following the increase in the transversal dimensions thereof during the testing of the device under test.

According to an aspect of the present invention, the contact probe can comprise stop means formed on the body thereof and configured to mechanically contact at least one portion of the guide so as to cause the retention of the contact probe inside the probe head.

According to an aspect of the present invention, the stop means can comprise a stopper having a transversal extension such as to define at least one shoulder configured to abut onto a face of the guide, said face being opposite a face of the guide facing towards the device under test (on the whole, the stopper joined to the probe body portion can have a transversal extension which is greater than the one of the guide hole for a suitable retention of the contact probe).

In addition or as an alternative, the stop means can comprise at least one clip configured to mechanically interfere with the guide hole and to contact a corresponding wall of said guide hole, this clip projecting from the body of the contact probe and being configured to elastically deform during the contact with the wall of the guide hole, thereby causing the retention of the contact probe by mechanical interference with the guide hole.

According to an aspect of the present invention, the contact probe can comprise an elastic portion arranged between the stop means, in particular the stopper, and the second end thereof, this elastic portion being configured to be pre-compressed under rest conditions after the assembly of the probe head and to exert, once pre-compressed, a pre-load force at least along the longitudinal axis.

According to an aspect of the present invention, the elastically compliant intermediate section can be embedded in a polymeric material.

According to an aspect of the present invention, the guide can comprise a first guide comprising respective first guide holes, and a second guide comprising respective second guide holes, wherein the elastically compliant intermediate section is arranged at at least one of said first guide holes and second guide holes, and wherein the contact probe further comprises intermediate stop means arranged between the first guide and the second guide, said intermediate stop means being configured to mechanically contact at least one portion of the first guide and/or second guide for the retention of the contact probe inside the probe head.

According to an aspect of the present invention, the intermediate stop means can comprise an intermediate stopper having a transversal extension such as to define at least one shoulder configured to abut onto a face of the first guide and/or of the second guide (as previously seen, on the whole, the stopper joined to the probe body portion can have a transversal extension which is greater than the one of the guide holes for a suitable retention of the contact probe).

According to an aspect of the present invention, the intermediate stop means can comprise a retention element shaped as an elastic hook, which is configured to elastically deform during the insertion of the contact probe through one of the first guide hole or the second guide hole and during the extraction of said contact probe through the other one of said first guide hole and second guide hole. The retention element, when housed between the first guide and the second guide, is in a non-deformed configuration and is adapted to mechanically contact the first guide and/or the second guide for the retention of the contact probe.

The features and advantages of the probe head according to the invention will be apparent from the following description of an exemplary embodiment thereof given by way of non-limiting example with reference to the attached drawings.

### BRIEF DESCRIPTION OF THE DRAWINGS

In the Drawings:

FIG. 1 schematically shows a probe head according to the present invention;

FIG. 2 shows contact probes of the probe head according to various embodiments of the present invention;

FIG. 3 schematically shows a probe head according to an embodiment of the present invention which provides two overlapped guide portions;

FIG. 4 schematically shows a probe head according to an embodiment of the present invention which envisages the presence of a lower guide and of an upper guide;

FIGS. 5 to 11 schematically show probe heads with contact probes according to different embodiments of the present invention, in particular with different geometries;

FIG. 12 schematically shows a probe head according to an embodiment of the present invention which envisages the presence of conductive portions to short-circuit groups of probes;

FIGS. 13 to 15 schematically show embodiments of the present invention wherein conductive portions are arranged in various ways at a guide of the probe head;

FIGS. 16A-16B and 17A-17B schematically show a probe head according to an embodiment of the present invention;

FIG. 18 schematically shows a probe head according to an embodiment of the present invention wherein the contact probe comprises stop means in the form of a stopper;

FIG. 19 schematically shows a probe head according to an embodiment of the present invention wherein the contact probe comprises stop means in the form of clips;

FIG. 20 shows a combination of the embodiments of FIGS. 18 and 19;

FIG. 21A schematically shows a probe head according to an embodiment of the present invention wherein the stopper abuts onto a conductive portion, while FIG. 21B schematically shows a probe head according to an embodiment wherein the clips are in contact with the conductive portion;

FIG. 22 schematically shows a probe head according to an embodiment of the present invention wherein there are non-rectilinear guide holes;

FIG. 23 schematically shows a probe head according to an embodiment of the present invention wherein there are multiple elastically compliant intermediate sections separated by more rigid portions of the probe body;

FIG. 24 schematically shows a probe head according to an embodiment of the present invention wherein there is a pre-load elastic portion;

FIG. 25 schematically shows a probe head according to a further embodiment of the present invention;

FIGS. 26 and 26bis schematically show a probe head according to an embodiment wherein the elastically compliant intermediate section is embedded in a polymeric material;

FIGS. 27A and 27B schematically show a probe head according to an embodiment of the present invention wherein there is a non-rectilinear elastically compliant intermediate section;

FIG. 28 schematically shows a probe head according to an embodiment of the present invention wherein there is a pair of intermediate guides associated with each other;

FIG. 29 schematically shows a probe head according to an embodiment of the present invention;

FIG. 30 schematically shows a probe head according to an embodiment wherein an intermediate stopper arranged between two intermediate guides comprises a plurality of projections;

FIG. 31 schematically shows a probe head according to an embodiment of the present invention which envisages the presence of an additional upper stopper;

FIG. 32 schematically shows a probe head according to an embodiment of the present invention;

FIG. 33 schematically shows a probe head according to a further embodiment of the present invention;

FIG. 34 schematically shows a probe head according to an embodiment of the present invention wherein two intermediate guides separated from each other and two elastic sections are provided;

FIG. 35 schematically shows a probe head according to a further embodiment of the present invention;

FIG. 36 schematically shows a probe head according to a further embodiment of the present invention;

FIG. 37 schematically shows a probe head according to a further embodiment of the present invention;

FIG. 38 schematically shows a probe head according to a further embodiment of the present invention;

FIGS. 39 and 39bis schematically show a probe head according to further embodiments wherein an end of the contact probe comprises a laterally projecting arm;

FIGS. 40 and 40bis schematically show a probe head according to further embodiments of the present invention;

FIG. 41 schematically shows a probe head according to a further embodiment of the present invention; and

FIGS. 42 to 46 show various embodiments of the present invention.

### DETAILED DESCRIPTION

With the reference to the figures, a probe head for the testing of electronic devices manufactured according to the present invention is globally and schematically indicated with 100.

It should be noted that the figures are schematic views and are not drawn to scale, but they are instead drawn so as to emphasize the important features of the invention. Furthermore, in the figures, the different elements are schematically represented and their shape can to vary depending on the desired application. Moreover, it should be noted that, in the figures, identical reference numbers refer to elements which are identical in shape or function. Finally, particular expedients described in relation to an embodiment illustrated in a figure can also be used for the other embodiments illustrated in the other figures.

Moreover, it is noted that, unless expressly stated, described process steps can also be reversed if necessary.

The probe head 100 is adapted to connect (directly or more preferably indirectly by means of a space transformer and/or a PCB) with an equipment (not illustrated in the figures) to perform the testing of electronic devices integrated on a semiconductor wafer 20, for instance (but not necessarily) high-frequency devices.

It is noted that, in the context of the present invention, the term “probe head” is used to indicate a test device without being limited by the presence or absence of particular components in addition to what is defined by the attached claims. In general, this term thus indicates a set of components which can be associated with further components for checking devices integrated on the above semiconductor wafer 20, and thus it generally indicates a system for measuring electronic devices.

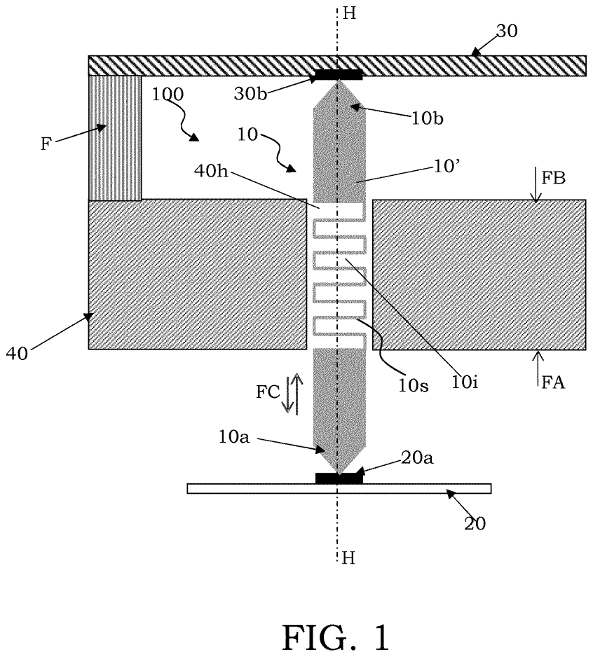

With the reference to the sectional view of FIG. 1, the probe head 100 first of all comprises a plurality of contact probes 10 intended to electrically contact the devices under test integrated in the semiconductor wafer 20 with the testing apparatus.

In order to house the contact probes 10, the probe head 100 comprises at least one guide 40 equipped with guide holes 40h inside which said contact probes 10 are housed. The guide 40 thus allows, together with the guide holes 40h thereof, to house, in particular to slidingly house, at least one portion of the contact probes 10.

Each contact probe 10 comprises a probe body 10′ extending along a longitudinal axis (indicated with the reference H-H) between a first end 10a and a second end 10b, which ends are adapted to contact respective pads or contact pads. By way of example, the first end 10a (also called contact tip and indicated in the field with the term “plunger”) is adapted to contact pads 20a of the device under test integrated on the semiconductor wafer 20, while the second and opposite end 10b (also called contact head) is adapted to contact pads 30b of a space transformer or of a printed circuit board (PCB) which can be associated with the probe head 100, said component being generically identified with the numeral reference 30 and being generically defined as “interface card”. In general, the term “end” thus means the terminal portions of the contact probe 10, said terminal portions comprising the contact points of the probe with the pads.

In an embodiment (as illustrated by simple way of example), the pads 30b are the pads of a PCB board, even if the use of an interposer arranged between the PCB and the contact heads of the probes is obviously not excluded.

Clearly, although the ends 10a and 10b in the attached figures end with a pointed shape, they are not limited thereto and can have any shape which is suited to the needs and/or circumstances.

Moreover, it is noted that, although the figures show for simplicity a single contact probe 10, the probe head 100 can comprise any number of contact probes, depending on the various applications.

In the embodiment of FIG. 1, a frame F acting as a structural support for the probe head 100 as a whole is also provided, in particular arranged between the guide 40 and the PCB 30, this frame F being omitted in the following figures only for simplicity of illustration.

Suitably, in order to enable high-frequency tests with high performances, the contact probe 10 has a reduced length, which is in particular lower than 2000 μm, preferably lower than 1000 μm, still more preferably equal to or lower than 800 μm, said length being measured along the longitudinal axis H-H of the probe. The self-inductance phenomenon is thereby suitably reduced and an effective testing also at very high frequencies, even in the radiofrequency domain, is ensured.

Advantageously according to the present invention, in order to ensure a proper contact with the pads 20a and 30b, in particular in order to ensure a proper control of the contact force, the contact probe 10 comprises at least one intermediate section 10s arranged between the first end 10a and the second end 10b which is elastically compliant (or yielding) at least along the longitudinal axis H-H. The elastically compliant intermediate section 10s (also indicated below as “elastic section” of the probe) is configured to define the contact force FC (in particular the direction and/or intensity thereof) exerted by the contact probe 10 on the pads 20a and/or 30b, i.e. said contact force FC can be controlled due to the structure (shape/size) of said elastically compliant intermediate section 10s, and the probe acts as a spring.

In particular, in a preferred embodiment, the elastically compliant intermediate section 10s is suitably configured so that the contact probe 10 exerts onto the contact pads 20a and 30b a contact force FC substantially directed along the longitudinal axis H-H, even if in other embodiments there can be forces also with other components (for instance such as to generate also a scrub movement: in fact configurations in which the elastically compliant intermediate section is configured to generate a torsion on the pad, or a transversal scrub, are possible; in fact some embodiments can provide elastically weaker portions and elastically stronger portions of the elastically compliant intermediate section 10s, as well as helical, not necessarily symmetrical shapes for said elastically compliant intermediate section 10s).

The presence of a contact force FC mainly in the longitudinal direction (with negligible transversal component) reduces the risks of interlocking of the contact probe 10.

As mentioned, in accordance with embodiments of the present invention, the contact force FC can also have a transversal component, i.e. the elastically compliant intermediate section 10s can be configured so that the contact force FC exerted by the contact probe 10 onto the contact pads has both a longitudinal/axial component and a transversal component, causing for instance a scrub of the contact tips.

In an embodiment of the present invention, the elastically compliant intermediate section 10s can comprise an elastically weaker wall of an opposite wall thereof, thereby causing a lateral movement during the overtravel.

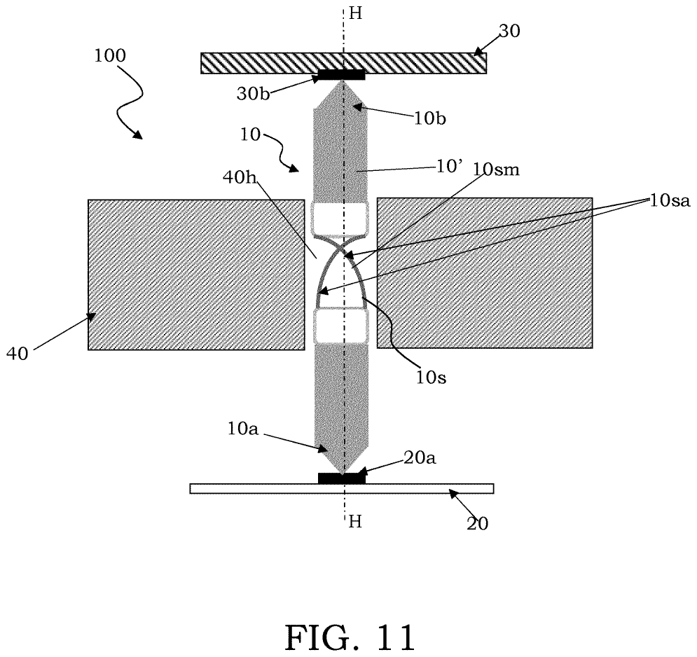

According to an embodiment of the present invention, the elastically compliant intermediate section 10s can comprise an elastic deformation mechanism (also called further elastic element, as it will be described hereafter in relation to FIG. 11) comprising arms having a different elasticity (in which for instance an arm can be elastically weaker than the other one), so that the elastic deformation of said section occurs not only in the longitudinal direction but also along other directions, causing for instance a scrub movement of the first end of the contact probe on the pads of the device under test.

According to an aspect of the present invention, the elastically compliant intermediate section 10s can also be configured to perform a torsion during the contact with the device under test and thus during the overtravel.

In a non-limiting example of the present invention, the elastically compliant intermediate section 10s can be obtained by interdigitated engravings or notches 10i formed in the body 10′ of the contact probe 10, said interdigitated engravings or notches 10i being configured so that the contact probe 10 substantially acts as an elastic spring. The substantially spring-shaped elastically compliant intermediate section 10s can thus be formed for instance by removing some material, wherein the above notches 10i are made symmetrically with respect to the longitudinal axis H-H of the contact probe 10 (even if this is not strictly necessary and asymmetrical shapes with respect to said axis can be provided).

In general, the present invention is not limited by the particular method for manufacturing the contact probe 10, what matters is the presence of the above elastic section comprising a plurality of turns which follow each other along the longitudinal axis H-H, where the term “turn” indicates in the present description the single elastic element (or elastic sub-portion) of the spring which is repeated along said longitudinal axis H-H, thereby forming a given elastic pattern, without being limited by a particular shape (for instance it does not necessarily display a cross-sectional circular profile as in a spiral spring, even if such a configuration is obviously possible), as it will be detailed hereafter.

The intermediate section 10s is thus elastically compliant in a mainly longitudinal direction (but in other configurations other directions for the deformation of the elastic section and thus for the contact force FC can also be provided, as mentioned above) so as to get compressed along said direction during the testing of the device under test. In particular, the elastically compliant intermediate section 10s allows the contact probe 10 to shorten along the longitudinal direction thereof during the normal operation of the probe head 100, with a “spring effect” which ensures a proper contact force during the overdrive and which also allows the contact probe 10 to come back to the original dimensions thereof once said probe head 100 has been spaced apart from the device under test.

It should be noted that, in the above-discussed embodiment, the contact probe 10 exerts onto the pads the above contact force FC substantially directed along the longitudinal axis H-H, while the component in the direction which is perpendicular to said longitudinal axis H-H is substantially null (or in any case reduced), thereby eliminating the risk of interlocking of the contact probe 10 in the guide hole 40h.

Preferably, the contact probe 10 has a non-circular cross section; in a preferred embodiment, the contact probe 10 has a rectangular section, for instance with one side having a length of 30 μm and the other side of the rectangle having a length of 70 μm, even if other dimensions can be obviously provided.

Furthermore, it is noted that the contact probe 10 can be made of a composite material, such as for instance layers of Pd, PdCo, Ni, NiCo, Au, Pt, Ag, Rh, and the like, without, however, being limited by the particular material used or by the manufacturing method. In general, selections of various materials or combinations of materials (such as for instance the above-described materials or combinations thereof) are possible depending on the needs and/or circumstances.

The elastically compliant intermediate section 10s extends along the longitudinal axis H-H of the contact probe 10 by a length of 1000 μm to 80 μm (preferably about 200 μm), and with a pitch (i.e. a distance at rest between the centres of two adjacent turns) of 100 μm to 5 μm.

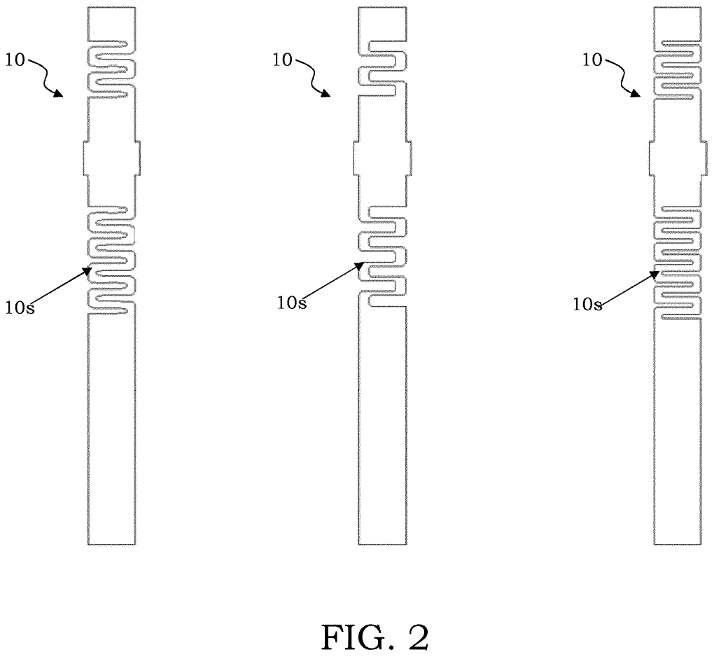

FIG. 2 shows contact probes manufactured according to different designs and different pitches of the respective elastic section, for instance with a different number of loops and with different thicknesses for the single turns from one embodiment to another one. Other shapes for the elastically compliant intermediate section 10s will be also illustrated hereafter.

In an embodiment, the elastically compliant intermediate section 10s is formed so that the ends of this section are always on a same side of the contact probe 10.

In the case in which an elastically compliant intermediate section 10s with a greater length is manufactured (always for the same overall length of the contact probe 10, which, as previously seen, is lower than 2000 μm, preferably equal to or lower than 800 μm), the stresses which the contact probe 10 is subjected to could be decreased.

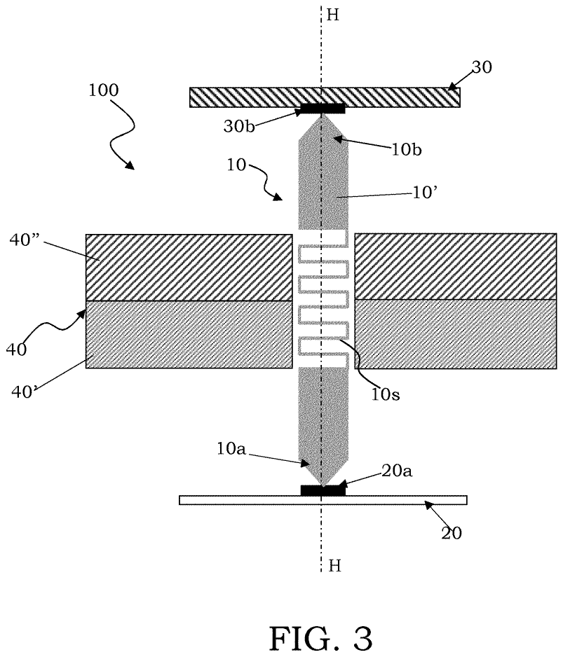

In order to accommodate the elastically compliant intermediate section 10s, a deep guide hole 40h is thus to be formed (for instance having a length which is higher than 300 μm). As illustrated in FIG. 3, in order to overcome this problem, instead of using a single guide 40 having a high thickness, two or more guides having a lower thickness associated with each other can be used. In other words, in an embodiment, the guide 40 can comprise a first guide portion 40′ and a second guide portion 40″. The second guide portion 40″ is initially made structurally independent from the first guide portion 40′ and is subsequently associated therewith, in particular it is fitted on the contact probe 10 after the latter has been introduced into the first guide portion 40′. For instance, the second guide portion 40″ can be overlapped to the first guide portion 40′, as well as it can be constrained thereto by attachment means, without limiting the present invention to particular attachment modes. Thereby, the guide holes of the single guide portions have smaller depths compared to the case in which a single guide is used, simplifying the formation of said holes.

A preferred embodiment has been described so far, in which a single guide 40 is provided (for instance having an overall thickness which is equal to 320 μm, even if other thicknesses are obviously possible, for instance higher thicknesses, thus allowing to extend the elastic section of the contact probe) and in which the elastically compliant intermediate section 10s is positioned at the guide 40 so as to be at least partially accommodated in the guide hole 40h, substantially in an intermediate position. In other words, an embodiment which envisages the presence of a single intermediate guide 40 which accommodates the elastic section of the contact probe 10 has been described so far. This embodiment is distinguished by a greater simplicity of assembly and lower production costs.

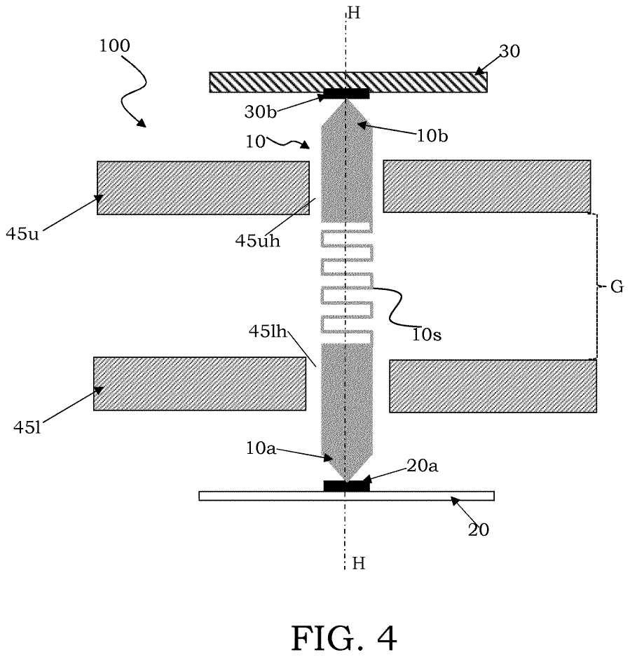

Alternatively, with reference to FIG. 4, the probe head 100 can comprise a lower guide 451 and an upper guide 45u separated from each other by an air gap or gap G, at which the elastically compliant intermediate section 10s lies, thus with the possibility of increasing the extension of this elastic section. The lower guide 451 and the upper guide 45u comprise respective lower guide holes 451h and upper guide holes 45uh for housing the contact probes 10.

In an embodiment (not illustrated in the figures), the lower guide holes 451h and the upper guide holes 45uh can possibly be unaligned with respect to each other, i.e., with reference to a single probe, the centres thereof do not lie on a same longitudinal axis, thereby creating a slight deformation of the contact probe 10 to favour the retention and the possible contact thereof with the walls of the holes.

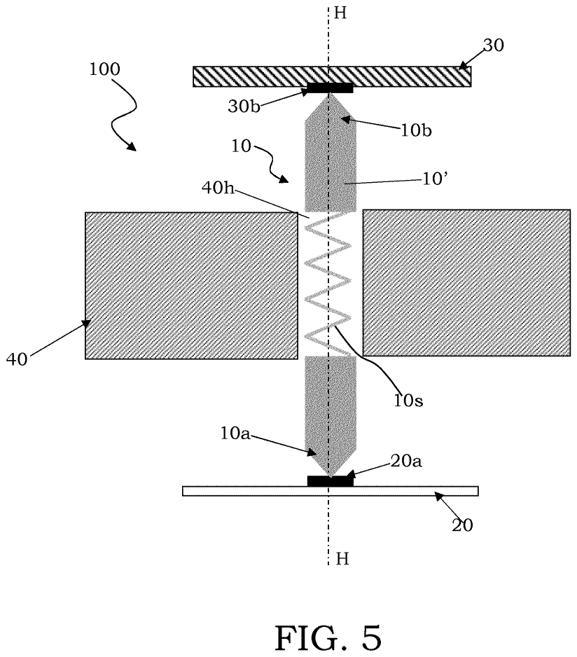

Referring now to FIGS. 5 to 11, various shapes are possible for the elastically compliant intermediate section 10s, in addition to the standard shape represented in FIGS. 1 to 4, wherein the elastic section is formed by elastic elements which appear as steps in the sectional views shown. In these various shapes, single elastic elements (being different from one shape to another one) are defined, which are repeated along the longitudinal axis H-H so as to define different elastic patterns, which different mechanical properties of the contact probe 10 correspond to.

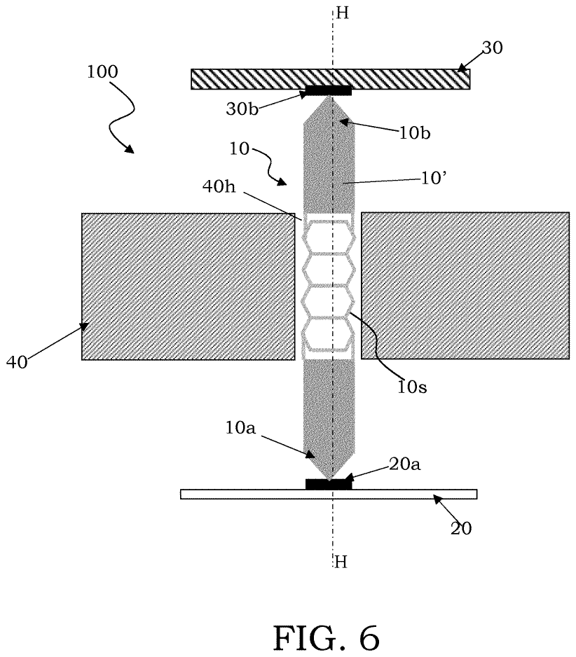

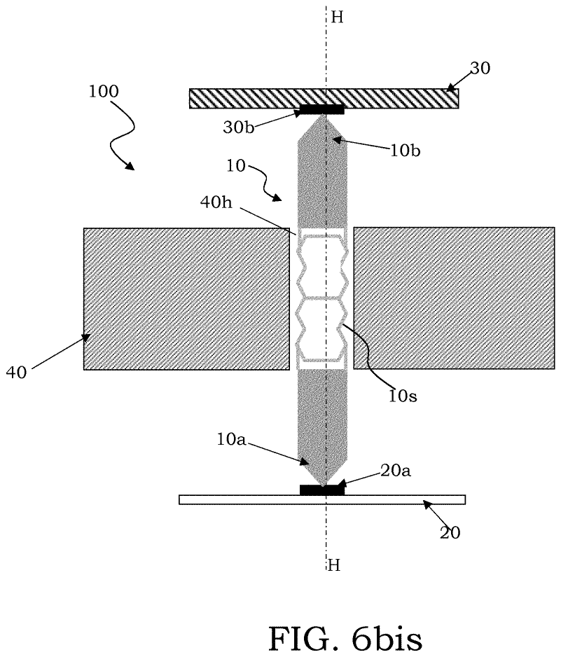

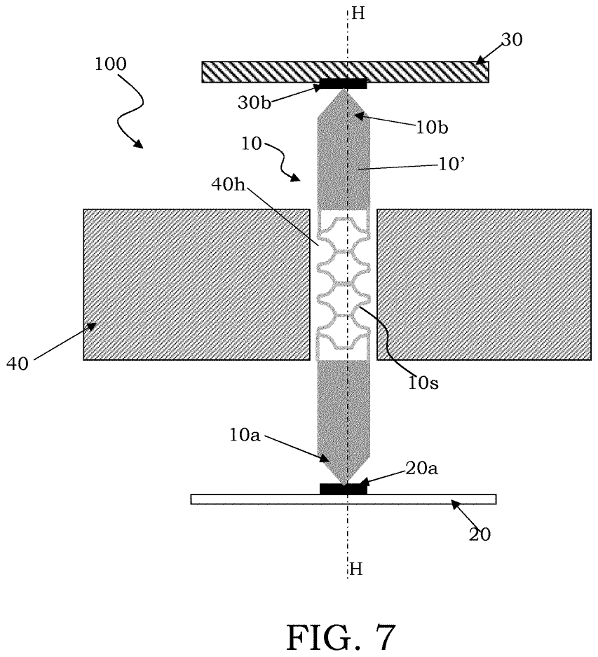

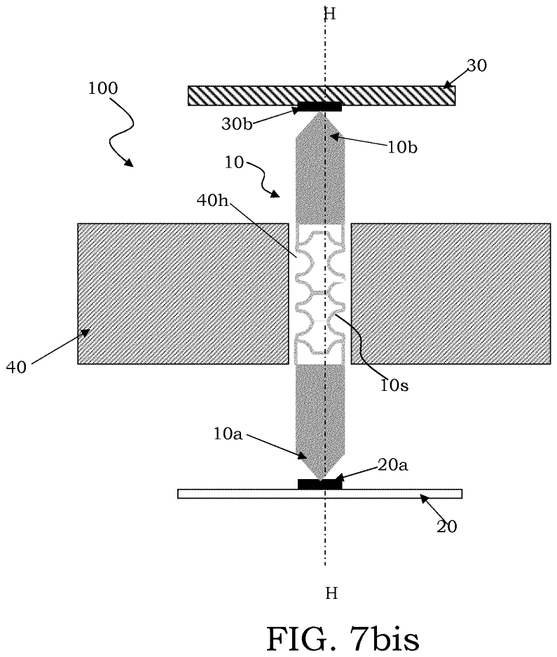

For instance, among the various possible geometries, the elastically compliant intermediate section 10s can have a shape with a sawtooth development (FIG. 5), or a spiral shape, or it can even be structured as a plurality elastic elements having, in a longitudinal section, the shape of polygonal elements connected to each other and which follow each other, such as for instance a succession of interconnected hexagons (FIGS. 6 and 7). Said polygonal elements can have a closed profile (i.e. they can have areas not communicating with each other), even if this is not necessary and embodiments in which the various connected polygonal elements have areas communicating with each other, even only for a short section, can be provided.

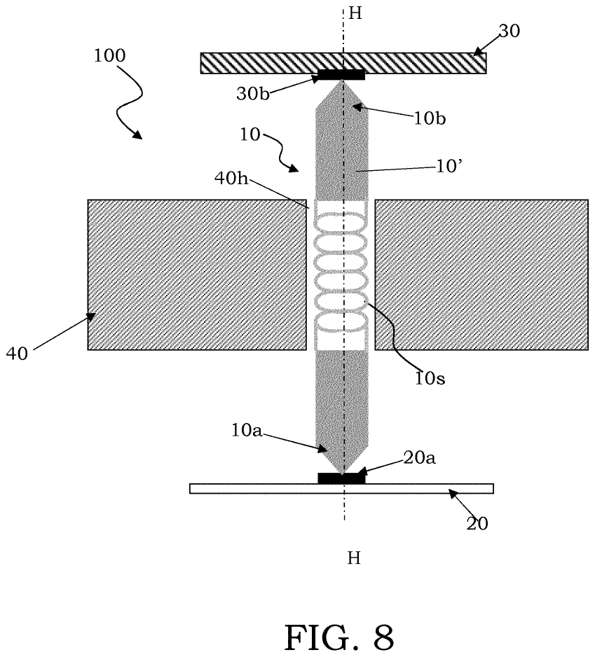

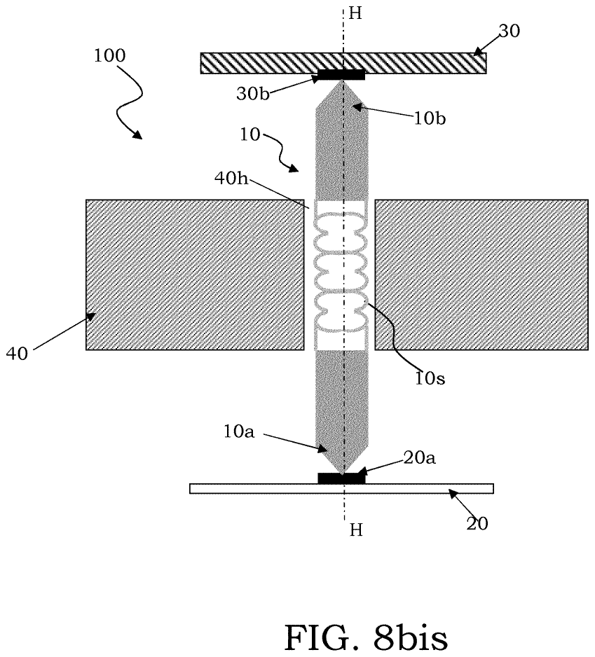

Alternatively, the elastically compliant intermediate section 10s can be structured as a plurality of elastic elements having each the shape of interconnected elements with an oblong profile (oval for instance) and which follow each other along the longitudinal axis H-H (FIG. 8), each one of said elements with the oblong profile developing along an axis of symmetry which is substantially orthogonal to the longitudinal axis H-H of the contact probe 10 and being slightly squashed in the centre thereof.

More particularly, with reference to the above-described geometries, the embodiment of FIG. 5 allows the overdrive of the contact probe 10 to be increased, the embodiment of FIG. 6 helps to keep the contact probe 10 in a straight configuration, but at the same time it increases the force and rigidity thereof, while the embodiment of FIG. 7, in which the slanted sides of the hexagon are replaced by curvilinear sections, helps to keep the contact probe 10 in a straight configuration as in FIG. 6 but at the same time it increases the flexibility and reduces the strength thereof. The embodiment of FIG. 8 simulates the effect of two joined standard springs, with the purpose of increasing the symmetry and keeping a good flexibility of the contact probe 10.

Furthermore, the variants shown in FIG. 6bis, 7bis and 8bis correspond to the geometries of FIGS. 6, 7 and 8 respectively, except that the single elastic elements of said previous figures are now grouped in interconnected pairs, each pair being defined by a single closed or half-closed profile, with the purpose of further reducing the rigidity of the elastic section and thus of the contact probe 10 as a whole.

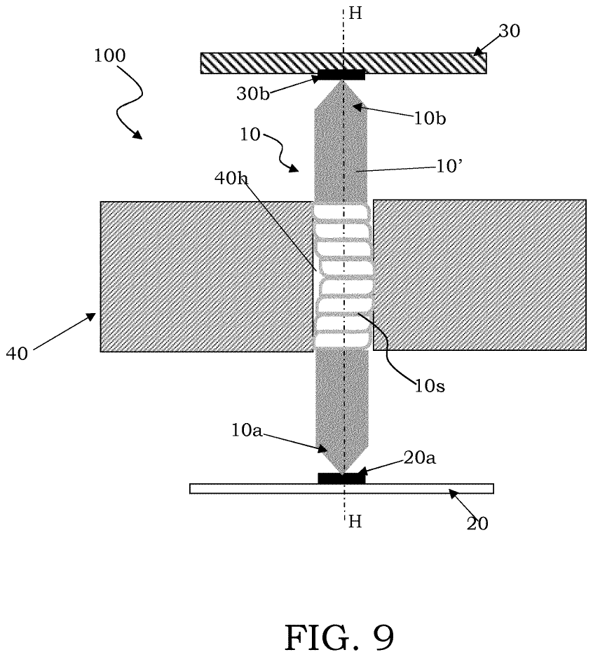

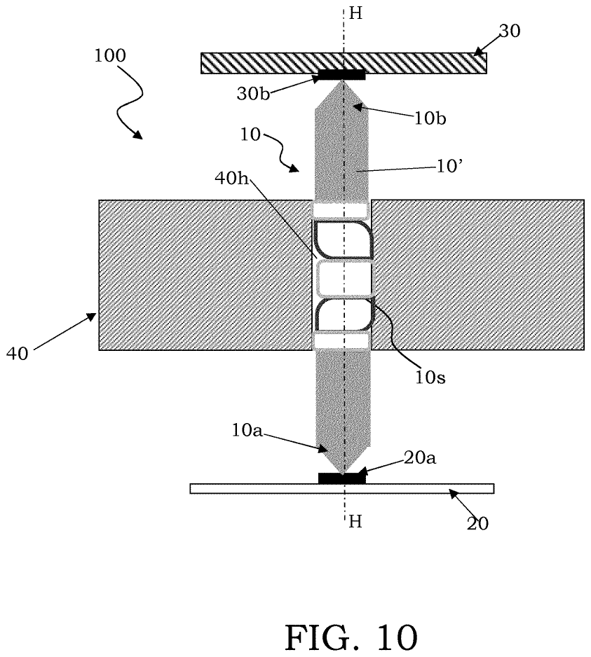

Furthermore, referring now to the embodiment shown in FIG. 9, the elastically compliant intermediate section 10s is formed by a plurality of turns having an asymmetrical shape with respect to the longitudinal axis H-H, in which each of them defines (for instance when seen in section) a hysteresis-shaped curve. In other words, in this embodiment, the asymmetrical shape of the turn is such that, in section, two sides (for instance the greater sides) are offset with respect to each other. Thereby, the elastic section 10s has sectional dimensions which are greater than those of the guide hole 40h (as illustrated in FIG. 9), generating a friction between said elastic section 10s and the walls of said guide hole 40h which prevents the contact probes 10 from exiting the guide 40, for instance during the maintenance of the probe head 100, and which ensures a better electrical contact with possible metalized walls of the guide hole 40h, as it will be described below. FIG. 10 shows a case in which the various turns are not aligned along the same axis H-H, defining a non-rectilinear section, even if, in other examples, they can be aligned on the same axis H-H.

FIG. 10 shows a further embodiment which provides an elastically compliant intermediate section 10s in which turns defining a hysteresis-shaped closed curve (i.e. the elastic elements described in relation to previous FIG. 9) alternate with standard turns (for instance the standard turns of a spiral spring, or with any other suitable shape) along the longitudinal axis H-H of the contact probe 10.

Furthermore, FIG. 11 shows an embodiment in which, in the elastically compliant intermediate section 10s, standard turns are integrated with an elastic deformation mechanism, indicated here as “further elastic element 10sm” (bounce of the spring). In other words, in this embodiment, between two elastic elements subjected to deformation substantially along the longitudinal axis H-H (i.e. a standard deformation as previously described) it is possible to arrange the further elastic element 10sm having different deformation properties, for instance comprising arms 10sa having a different elasticity (in which for instance an arm can be elastically weaker than the other one). This helps to modify the properties of deformation of the elastic section 10s, which occurs not only in the longitudinal direction but also along other directions, causing for instance a scrub movement of the first end 10a of the contact probe 10 on the pads 20a of the device under test. Moreover, embodiments in which the elastically compliant intermediate section 10s is formed only by the above further elastic element 10sm are possible.

Obviously, the illustrated embodiments are only indicative and do not limit the scope of the present invention, while the various embodiments can be varied depending on the applications, or in some cases they can also combined with each other.

As it will be investigated in depth hereafter, another advantageous embodiment envisages a plurality of oblong-shaped rings, where, unlike what has been seen in FIG. 8, each one of said rings extends in length along the longitudinal axis H-H of the contact probe 10, in particular to facilitate the contact with walls of the guide hole 40h when these rings are compressed, which is advantageous in the case in which there are metallizations to short-circuit groups of probes with each other.

In this regard, it is known in the field that the fixed position of the power supply and ground signals (due for instance to the layout of the pads of the device under test) and the shape of the probes limit the control of the impedance of the signals inside the probe head, as well as they limit the control of the noise caused on the signal probes by other close signals, which limits the frequency performances of the probe head.

For this reason, in high-frequency applications (in particular RF applications), the ground probes (and also power supply ones) are short-circuited through a metallization on the guide, thus short-circuiting probes of a same domain and making the ground contact available inside the probe head to also connect possible shields. Moreover, in the case of devices with different ground/power supply domains on the device then joined on the PCB, the metallization allows the loop inductance between a power supply and the related ground to be reduced.

For instance, consider the case in which a given power supply of a device under test is contacted by a single probe, which is short-circuited with other probes which carry power supplies sharing the same power supply unit. In such a case, when the current of this power supply meets the metallization which short-circuits all the probes of this domain, it splits among all the short-circuited probes thereby allowing the inductance and equivalent resistance to be reduced compared to the case in which this current is confined in a single probe up to the PCB.

It is thus evident that the presence of metallizations on the guide, which short-circuit groups of probes and create a common conductive plane, allows the noise to be reduced and the frequency performances of the probe head to be increased.

Moreover, it is possible to short-circuit signal probes with each other as well, for instance based on the loop-back technique.

For this purpose, in accordance with embodiments of the present invention (as illustrated in FIG. 12), the guide 40 of the probe head 100 comprises at least one conductive portion 21 which includes and electrically connects the holes of at least one group (indicated with the reference 40h′) of the guide holes 40h and which is adapted to contact, and thus to short-circuit, a corresponding group of contact probes, which are intended to carry a same type of signal, in particular intended to carry a given ground or power supply signal or operating signal.

Due to the conductive portion 21 formed on the guide 40, also indicated below as “metallization 21”, it is possible to form a given conductive domain, in which at least one portion of the contact probe 10 is in contact with said conductive portion 21.

In the non-limiting example of FIG. 12, two contact probes short-circuited by the conductive portion 21 and a contact probe electrically insulated from them are depicted, even if this is obviously only a schematic example and any number can be provided.

By way of example, the contact probes 10 short-circuited with each other by the conductive portion 21 can be contact probes intended to carry ground signals, as well as they can be contact probes intended to carry the power supplies. In other words, in the probe head 100, the contact probes short-circuited with each other due to the metallization of the guide 40 and housed in the group 40h′ of the guide holes 40h are adapted to carry a same ground or power supply signal, with resulting increase in the performances of the probe head.

Furthermore, as mentioned above, the short-circuited probes can also be contact probes intended to carry the input/output operating signals between the device under test and the testing apparatus interfaced with the probe head 100, as it occurs for instance in the loop-back technique.

In any case, the conductive portion 21 is such as to form a common conductive plane in the probe head, which is very useful, especially in the high-frequency testing that the short contact probes 10 are able to perform.

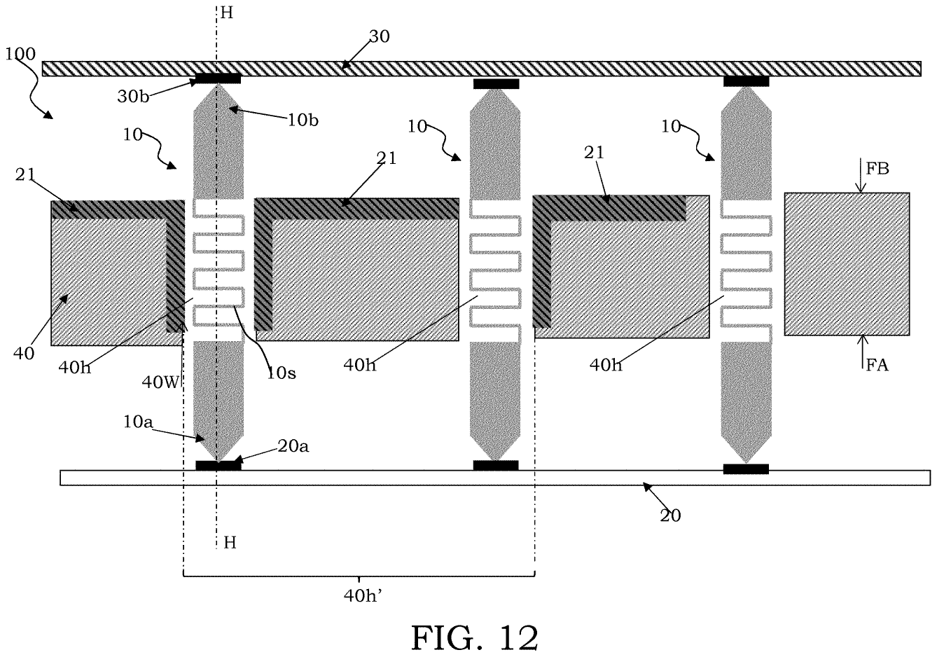

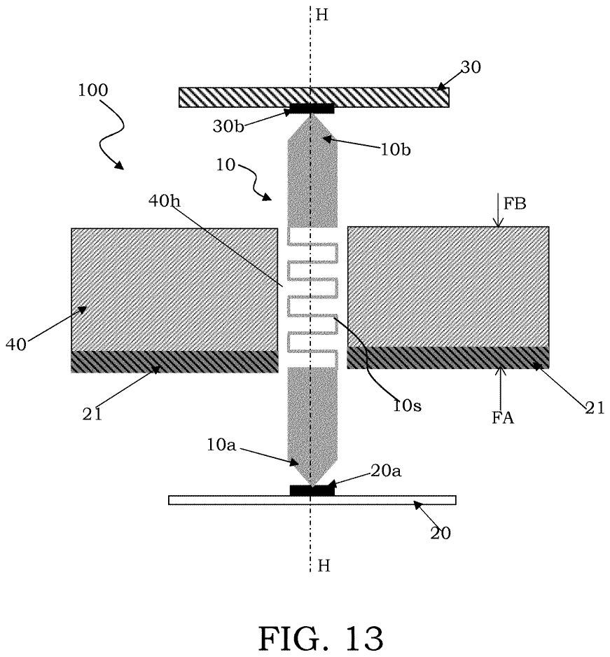

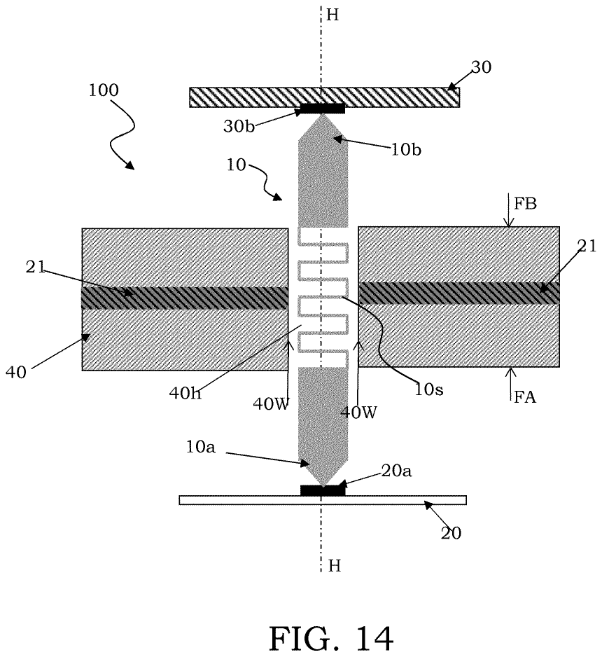

Obviously, the probe head 100 can comprise any number of conductive portions 21 arranged in any way on the guide or even embedded therein, to carry any type of signal. For instance, the conductive portion can be formed on an upper face FB of the guide 40 (as illustrated in FIG. 12), or it can be arranged on a lower face FA thereof (as illustrated in FIG. 13), as well as it can be formed inside said guide 40 (i.e. embedded in the guide 40, as represented in FIG. 14).

Moreover, it is possible to envisage the presence of a first conductive portion which short-circuits ground probes and a second conductive portion which short-circuits power supply probes arranged on an opposite face of the guide, as well as many other configurations can be provided, as described for instance in the International patent application number PCT/EP2017/082180 in the name of the Applicant.

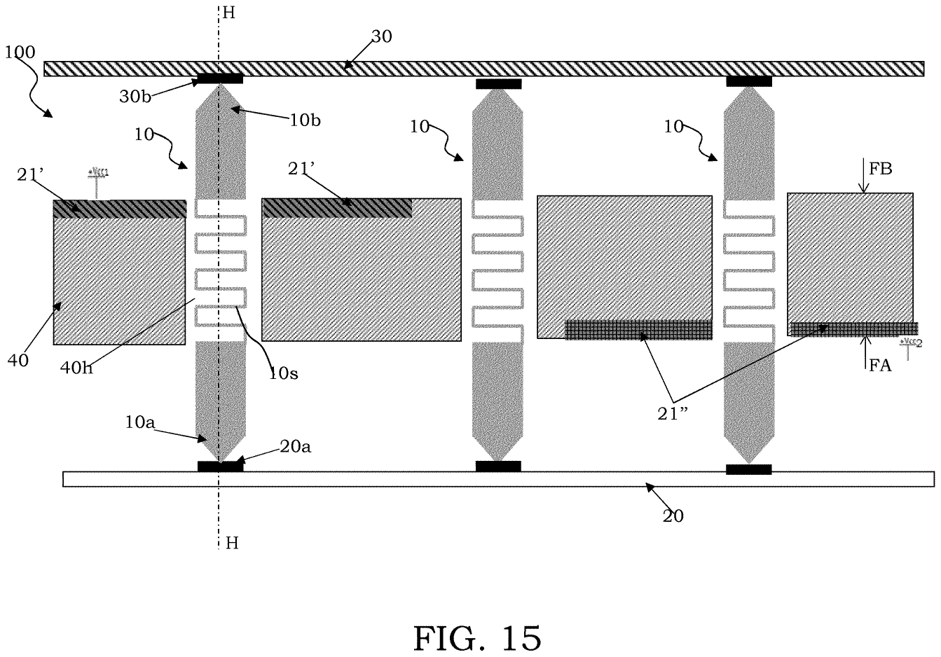

By mere way of example, as illustrated in FIG. 15, it is possible to provide a plurality of conductive portions 21′ and 21″ corresponding to a plurality of different conductive domains (for instance different power domains), these conductive portions 21′ and 21″ being arranged on opposite faces of the guide 40 (as illustrated in the non-limiting example of FIG. 15) and/or embedded in said guide 40, or even on the same face of the guide 40.

Also the manufacturing method of the conductive portion is not limited to a particular one, for instance it can be formed by depositing conductive material on the ceramic guide.

In other words, the present invention is not limited by the number and arrangement of the conductive portions, which can be set based on the needs and/or circumstances.

In any case, what matters is that the presence of the at least one conductive portion 21 allows a common conductive plane to be formed, which electrically connects several contact probes to each other (i.e. the contact probes 10 housed in the group of holes 40h′), which, as previously seen, are equipped with the elastically compliant intermediate section 10s and have a reduced length, increasing the performances of the probe head 100 as a whole.

Furthermore, the conductive portion 21 can coat at least one portion of the walls (generically indicated with 40W, and with 40W1 and 40W2 to indicate opposite walls) of the guide holes of the group 40h′, thereby forming a metallized portion of the guide hole with which the contact probe 10 is in contact, in particular with which the contact probe 10 makes a sliding contact.

Preferably, the conductive portion 21 can entirely cover some or all the walls of the guide holes (and thus in this case the metallized portion coincides with the entire wall 40W of the holes), or it is possible to provide a configuration in which this conductive portion 21 only partially covers the wall 40W of the guide holes.

In accordance with embodiments of the present invention, the contact of the contact probe 10 with the conductive portion 21 occurs through at least one portion of the elastically compliant intermediate section 10s, which is properly configured to perform said contact, for instance it is a sliding contact; some examples will be illustrated below.

In general, the contact with the conductive portion 21 can occur through at least one portion of the elastically compliant intermediate section 10s, and/or through stop means of the contact probe 10, as it will be also detailed below: being a very short contact probe, it is thus advantageous to exploit these components for contacting the metallizations 21.

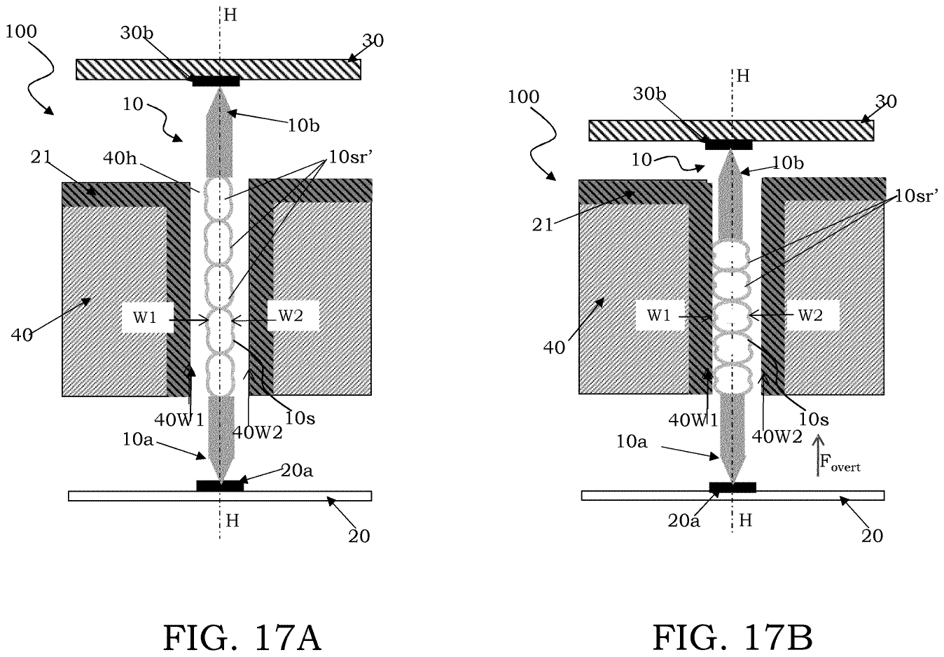

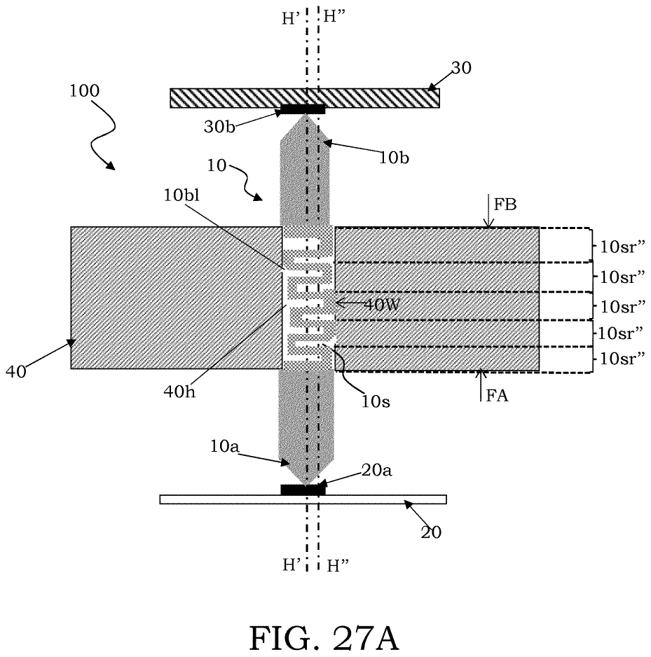

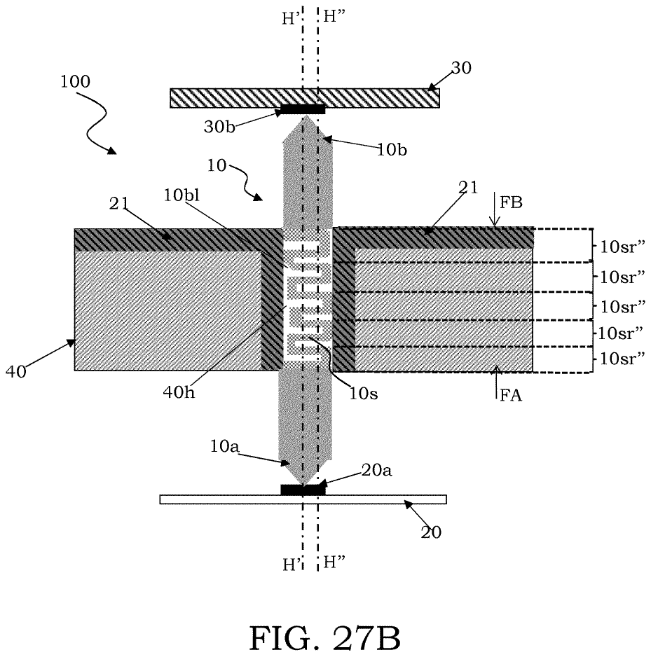

Moreover, it is noted that, although FIG. 12 and the followings show a probe having an elastically compliant intermediate section 10s with a step-like section, any geometry of the probe could be used with said conductive portion 21; in this regard, FIGS. 17A and 17B and 27B (discussed in detail below) show some of the many possible examples.

Given the importance of the conductive portion 21, there is thus the need to ensure an optimum contact between the contact probes 10 and said conductive portion 21 (for instance between the probes and the metallized walls of the guide holes) during the testing of the device, for instance there is the need to always ensure the above sliding contact between the probe and the hole (even if in some configurations this contact can be a pressing contact, for instance an abutment of a stopper on a conductive portion, as it will be discussed below).

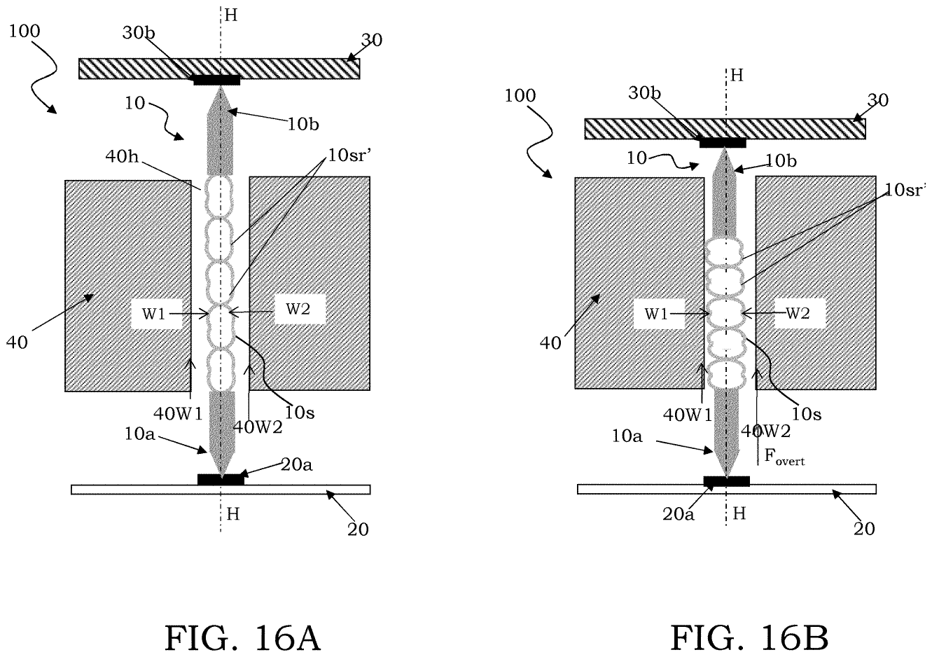

In an advantageous embodiment of the present invention, previously mentioned and now illustrated in detail in FIGS. 16A-16B and 17A-17B, in order to improve the electrical contact between the contact probes 10 and the conductive portion 21, the elastically compliant intermediate section 10s is structured as a plurality of interconnected elastic elements (or elastic sub-portions, reference 10sr′) which follow each other along the longitudinal axis H-H of the contact probe 10. As represented in the above figures, each one of the elastic elements 10sr′ is configured to be compressed under the action of the pressure generated during the testing of the device under test, and it is subjected, during said compression, to a reduction in its dimensions along the longitudinal axis H-H of the contact probe 10 and to an increase in its transversal dimensions, and thus it is subjected to a lateral bending which approaches it to the walls of the guide hole.

As illustrated in the example of FIGS. 16A-16B and 17A-17B, the elastic elements 10rs′ are shaped as interconnected rings, each one having an oblong shape with a longitudinal development along the longitudinal axis H-H of the contact probe 10, i.e. these rings are elongated in the longitudinal direction of the probe (in general they are thus elastic elements with an elongated shape along the longitudinal axis H-H), in order to increase the lateral bending. These rings can have a closed or half-closed profile.

The elastic elements 10sr′ are thereby configured to contact, through at least one side wall thereof (indicated with the references W1 and/or W2), the conductive portion 21 (which at least partially coats the wall of the guide hole 40h) following the increase in the transversal dimensions thereof during the testing of the device under test, ensuring an optimum contact with said metallization (as illustrated in FIG. 17B). In other words, once the overdrive is applied, the single rings swell contacting the corresponding wall portions of the guide hole 40h.

In an embodiment, a first wall (the wall W1 in the example of the figures) of at least one of the elastic elements 10sr′ facing a corresponding wall (the wall 40W1 in the example of the figures) of the guide hole 40h is elastically weaker than a second wall thereof (i.e. the wall W2 in this example) which is opposite it with respect to the longitudinal axis H-H. In general, it is possible to provide an embodiment in which an entire wall of the two walls of the elastic section has a lower elasticity, thus modifying the deformation properties of the contact probe 10, which does not deform symmetrically. Only one of the walls of the contact probe 10 thereby contacts the related metallization (i.e. the rings, by swelling, contact a single wall of the guide hole, in particular through the elastically less weak branch), thereby avoiding interlocking problems but ensuring at the same time an optimum contact, and possibly also generating a beneficial scrub movement of the contact tip.

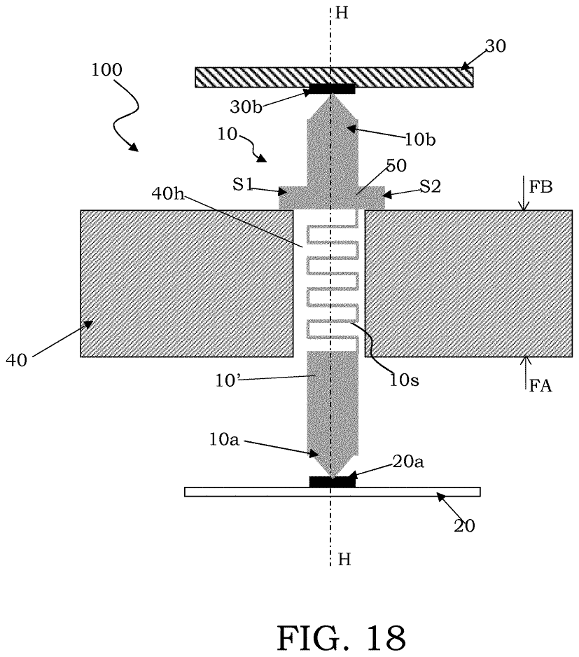

Referring now to FIG. 18, in an embodiment of the present invention, the contact probe 10 also comprises stop means formed on the body 10′ thereof and configured to mechanically contact at least one portion of the guide 40 so as to cause the retention of the probe inside the probe head 100.

The position of the contact probe 10 inside the probe head 100 can be thereby fixed, preventing it from slipping outside the guide hole 40h.

In the particular example of FIG. 18, the stop means are shaped as a stopper (indicated with the reference 50) having a transversal extension such as to define at least one shoulder (reference S1 or S2) configured to abut onto an upper face FB of the guide 40, i.e. abutting onto a face opposite a face FA facing towards the device under test (and thus having at least one abutting surface). The stopper 50 is thus protruding from at least one wall of the contact probe 10 (on the whole, the stopper 50 joined to the probe body portion can have a transversal extension which is greater than the one of the guide hole for a suitable retention of the contact probe).

In particular, in a preferred embodiment, the stopper 50 comprises two shoulders S1 and S2, which are symmetrical with respect to the longitudinal axis H-H of the contact probe 10, defining two surfaces for abutting onto the face FB of the guide 40. In any case, it is noted once again that the figures are only applicative examples of the present invention and other configurations for the stopper can obviously be adopted (for instance the stopper can protrude from a single wall of the contact probe 10 and not from two opposite walls as depicted, as well as it can have any suitable configuration).

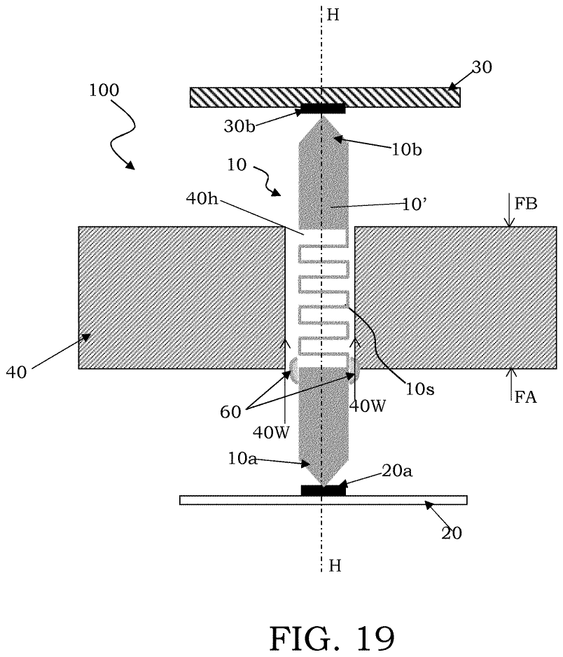

In addition or as an alternative, in an embodiment of the present invention represented in FIG. 19, the stop means of the probe comprise at least one clip 60 configured to mechanically interfere with the guide hole 40h and thereby to contact a wall 40W of said guide hole 40h. More particularly, the clip 60 projects from the body 10′ of the contact probe 10 and is configured to elastically deform during the contact with the wall 40W of the guide hole 40h, thereby causing the retention of the contact probe 10 by mechanical interference with said guide hole 40h.

In the example of the figures, the clip 60 is formed at the face FA of the guide 40, i.e. at the lower face facing towards the device under test DUT.

Due to the presence of the stopper 50 and/or of the clips 60, the contact probe 10 is thereby prevented from exiting the guide hole 40h when there is not the device under test and/or the PCB (and thus when in the latter case, when the probe head 100 is overturned), thus simplifying the management of the probe head 100.

In the preferred embodiment, there are two clips 60 arranged on the body 10′ symmetrically with respect to the longitudinal axis H-H, these clips 60 being adapted to contact respective walls 40W of the guide hole 40h, ensuring a mobile interlocking of the contact probe 10.

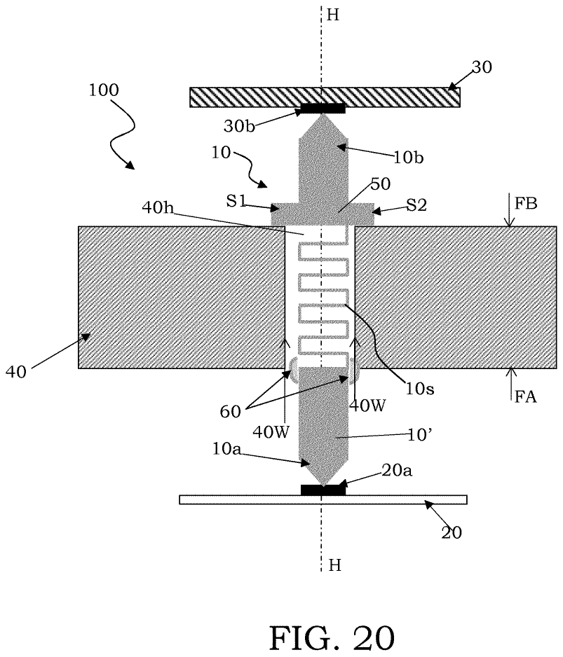

Obviously, a combination of the stopper 50 and the clips 60 can also be provided, as indicated in the example of FIG. 20.

In general, it is preferable that the clip 60 has a rigidity which is lower than the one of the elastically compliant intermediate section 10s, so as to avoid a deformation of the contact probe 10 during the assembly and ensure however a proper handling of the contact probe 10 along the longitudinal axis H-H during the test.

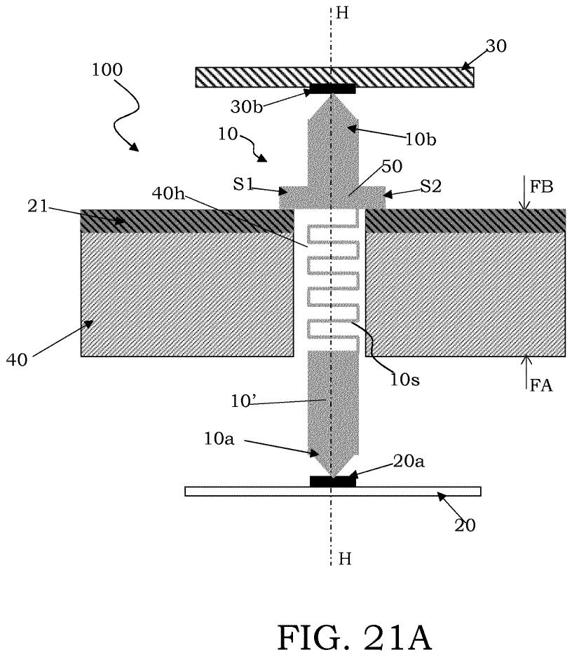

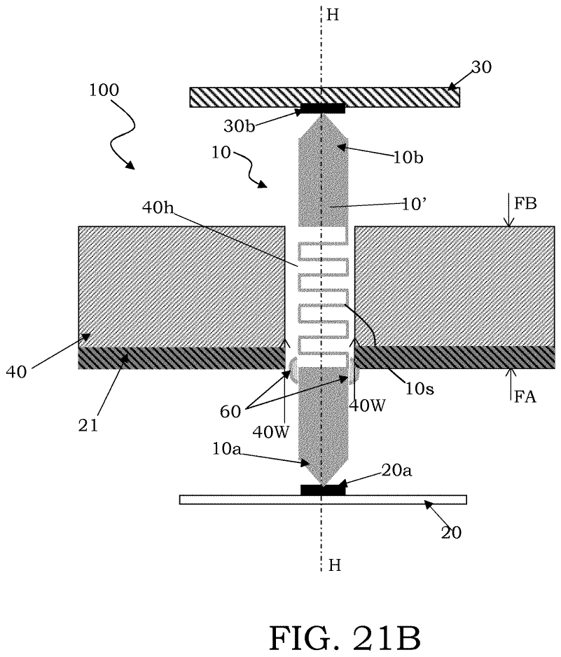

Suitably, in the case in which there is also the conductive portion 21 to short-circuit groups of probes, the contact of the contact probe 10 with the conductive portion 21 can be a pressing contact by means of the shoulder S1 and/or S2 of the stopper 50, as indicated in the example of FIG. 21A, or it can be a contact with one or more walls 40W of the guide hole 40h through one or more clips 60, as indicated in the example of FIG. 21B, or also a combination of both these embodiments. In addition or as an alternative, as previously mentioned and as it will be investigated in depth below, the contact of the contact probe 10 with the conductive portion 21 can be a sliding contact between at least one wall of the contact probe 10, in particular of the elastically compliant intermediate section 10s, and at least one corresponding wall 40W of the guide hole 40h.

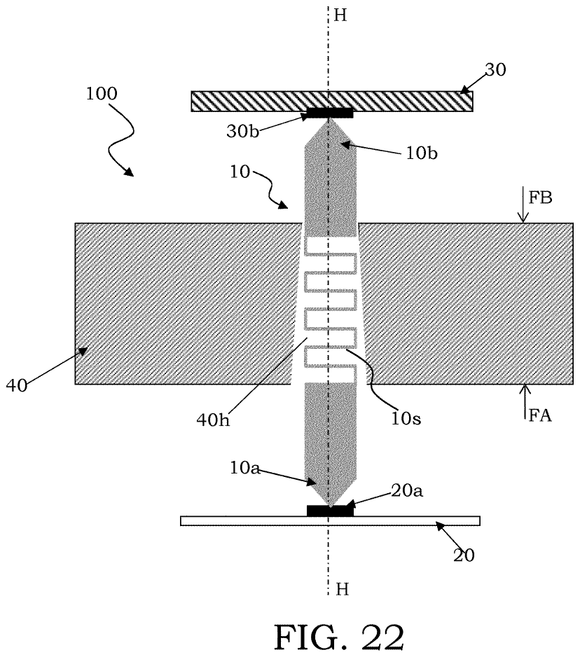

With regard to the retention of the contact probe 10, as illustrated in FIG. 22, it is also possible to provide an embodiment in which the guide hole 40h is not rectilinear (i.e. it has a non-rectilinear section), thereby preventing an extraction of said contact probe 10. In other words, at least one guide hole 40h of the guide 40 comprises at least one wall which is tilted with respect to the longitudinal axis H-H, said guide hole 22h having a non-rectilinear sectional shape. Preferably, the guide hole 40h comprises a pair of tilted opposite walls, suitably making the desired retention, without having to introduce stop means on the contact probe 10.

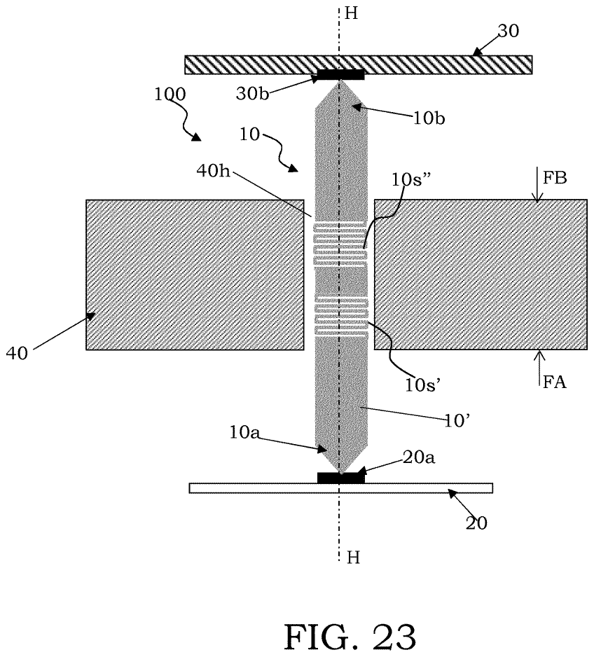

Furthermore, referring now to FIG. 23, in accordance with an embodiment of the present invention, the contact probe 10 comprises a plurality of elastically compliant intermediate sections 10s′ and 10s″ separated from each other by portions of the body 10′ of said contact probe 10, these elastically compliant intermediate sections 10s following each other along the longitudinal axis H-H. FIG. 23 shows an example in which there are two elastic sections, even if it is possible to provide a different number thereof.

The use of several elastically compliant intermediate sections involves an increase in the presence of the rigid portions of the contact probe 10, and such an embodiment can be implemented in order to adjust the moment of the probes and facilitate the handling thereof.

It is now noted that, in a real probe head comprising several contact probes, the probes have a different length with respect to each other, as well as the height of the probe head, for instance the distance between the guide and the PCB (substantially corresponding to the height of the frame F) can be lower than expected, for instance it can be the minimum height of the expected tolerance range. In this case, there is the risk that the contact with the PCB does not occur correctly and/or that the pressure exerted onto the contact probes 10 causes the deformation of the stopper 50.

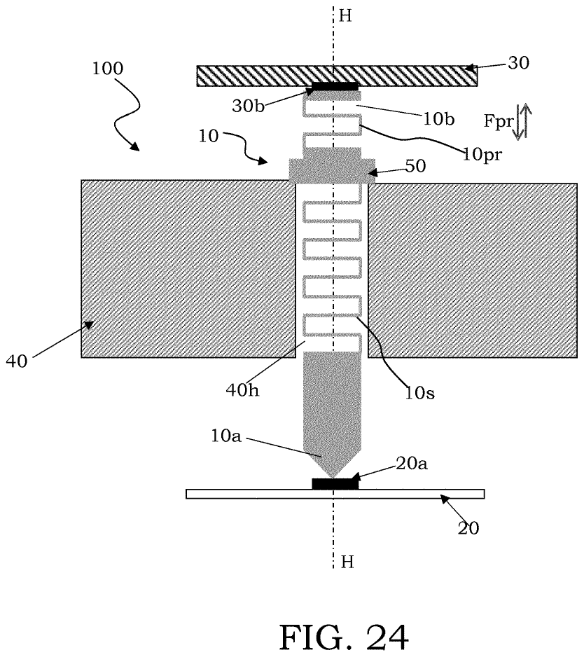

In order to solve this problem, in a very advantageous embodiment of the present invention illustrated in FIG. 24, the contact probe 10 comprises an elastic portion (indicated with the reference 10pr) arranged between the stopper 50 and the second end 10b thereof, i.e. in the non-driven area of the probe (in particular the non-driven upper area). This elastic portion 10pr is configured to be pre-compressed under rest conditions (i.e. when the testing is not performed) after the assembly of the probe head 100 and thus it is able to exert, once pre-compressed, a pre-load force Fpr, this force being substantially directed along the longitudinal axis H-H.

Thanks to this solution, the optimum contact of the contact probe 10 with the interface card 30 is always ensured, since the elastic portion 10pr ensures the suitable pre-compression of the contact probe 10, allowing it to adapt to the various tolerances/dimensions.

In this case, the contact force with the pads is thus generated not only by the overtravel of the contact probe 10, but also by the pre-load force exerted by the elastic portion 10pr.

The pre-load elastic portion 10pr also ensures an optimum damping of the contact with the pads, in addition to the one due to the elastically compliant intermediate section 10s.

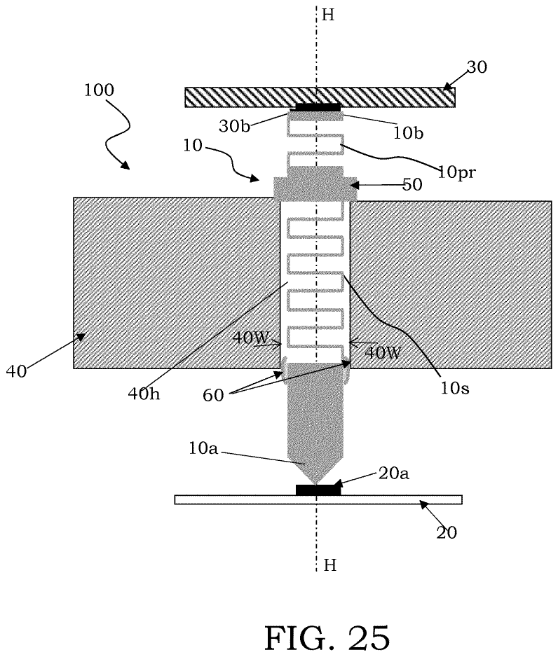

Obviously, as illustrated in FIG. 25, it is possible to combine the above solution (which provides the pre-load spring) with any one of the previous embodiments, and thus it is also possible to provide one or more clips 60 in addition to the stopper 50, one or more conductive portions 21, as well as many other configurations depending on the requirements and/or needs.

The pre-load elastic portion 10pr is formed for instance by removing some material from the probe body 10′, even if any suitable manufacturing method can be provided.

In an embodiment not illustrated in the figures, it is also possible to provide a plurality of pre-load elastic portions 10pr between the stopper 50 and the second end 10b, said pre-load elastic portions 10pr being separated from each other by portions of the body 10′ of the probe and following each other along the longitudinal axis H-H.

The pre-load elastic portion 10s has a length between 500 μm and 50 μm, for instance preferably between 100 μm and 50 μm, and the length thereof and the shape thereof are such as to ensure a proper pre-load force to the contact probe 10.

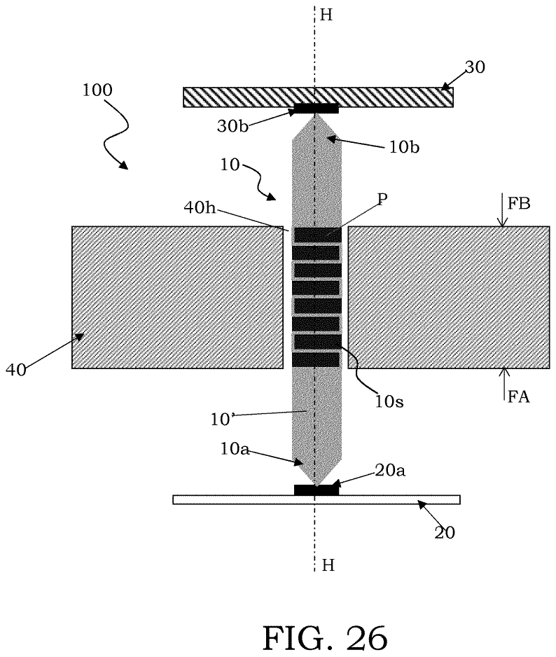

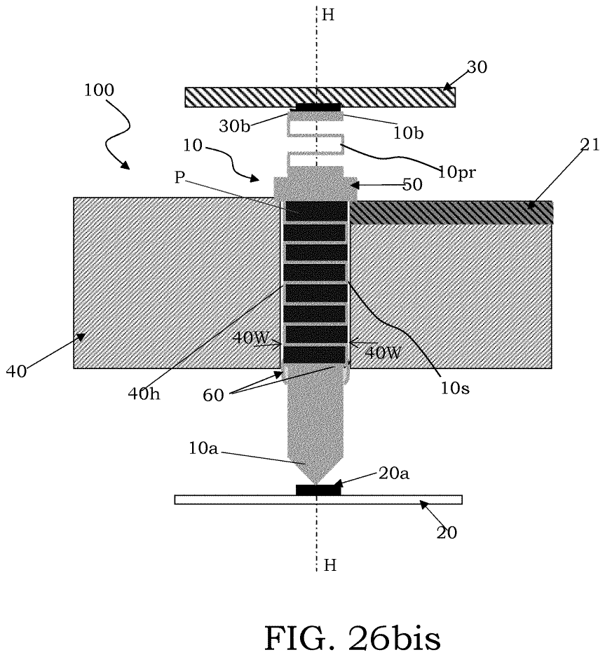

Referring now to the embodiment of FIG. 26, the elastically compliant intermediate section 10s is at least partially embedded in a polymeric material (identified herein with the reference P), which ensures a better mechanical stability of the contact probe 10 as a whole. For instance, the elastically compliant intermediate section 10s can be completely embedded in the polymeric material P, and thus in this case this material can completely extend in the guide hole 40h.

In an embodiment, the polymeric material P is polyamide or is selected from other materials which are similar to polyamide materials, even if the present invention is not limited in any way by the polymeric coating material used, since any suitable material can be selected based on the requirements.

In this case, the presence of the polymeric material P allows to increase the elastic response of the elastically compliant intermediate section 10s itself and to ensure a greater strength to lateral deformation.

Obviously, this embodiment can be combined with the other ones, such as for instance with the presence of the conductive portion 21, as well as with any one of the here-described geometries, or with any one of the configurations of the guide, as illustrated for instance in FIG. 26bis (possibly, although not illustrated, also the pre-load elastic portion 10pr can be embedded in a polymeric material).

Furthermore, in an embodiment illustrated in FIGS. 27A and 27B, the elastically compliant intermediate section 10s is split in a plurality of elastic sub-portions or elastic elements or elastic half-sections (in this case indicated with the reference 10sr″) which are not aligned with each other with respect to a same reference axis (for instance they are unaligned with each other with respect to the longitudinal axis H-H of the probe when taken as a reference).

For instance, the elastic elements 10sr″ develop along respective axes, possibly parallel to each other (indicated with the references H′-H′, H″-H″), not necessarily coinciding with the longitudinal axis H-H of the probe.

In this embodiment, the elastically compliant intermediate section 10s is thus formed by various sections (i.e. the elastic elements) which are not aligned along the longitudinal axis of the contact probe 10, i.e. along a vertical reference axis.

The elastic elements 10sr″ follow each other in series without interruption and are shifted (i.e. offset along the vertical reference axis) from each other so as to define an elastically compliant intermediate section which is not rectilinear as a whole, being the respective axes of symmetry non-coincident with each other (suitably shifted).

In general, in short, in accordance with this embodiment, the elastically compliant intermediate section 10s is thus structured as a plurality of elastic elements 10sr″ which follow each other in series so that said elastically compliant intermediate section is non-rectilinear in section, wherein at least one of said elastic elements is in contact with a wall of the guide hole. In particular, at least two of the elastic elements 10sr″ can be unaligned with each other with respect to a reference axis which is orthogonal to the guide, i.e. a vertical axis (for instance the longitudinal axis H-H of the contact probe 10, as previously seen).

Suitably, at least one of these elastic elements 10sr″ is in contact with a wall 40W of the guide hole 40h, in particular with the conductive portion 21 which extends in this hole (as illustrated in FIG. 27B), thus achieving the desired electrical contact with the metallization and at the same time the simple retention of the contact probe 10.

In accordance with an embodiment, one or more of the edges of the elastic elements 10sr″ (in particular the edges of the elastic elements in contact with the walls 40W of the guide hole 40h, i.e. the projecting portions) are bevelled (i.e. it comprises a bevelling 10bl), in order to avoid interlockings of the contact probe 10 in the guide hole, in particular to avoid interlockings during the assembly.

This embodiment, which envisages forming non-rectilinear or curved intermediate elastic sections, is advantageous since it ensures that, during the testing of the device under test, the contact probe 10 stays in place, while keeping a proper contact with the walls of the guide hole 40h and thus with the related metallization. In particular, in this embodiment (similarly to what is seen for the embodiment of FIG. 9), the elastic section 10s has (at least locally) sectional dimensions which are greater than the ones of the guide hole 40h (as illustrated in FIGS. 27A and 27B), generating a friction between said elastic section 10s and the walls of said guide hole 40h. This friction prevents the contact probes 10 from exiting the guide 40, for instance during the maintenance of the probe head 100, and ensures a better electrical contact with the conductive portion 21 (FIG. 27B).

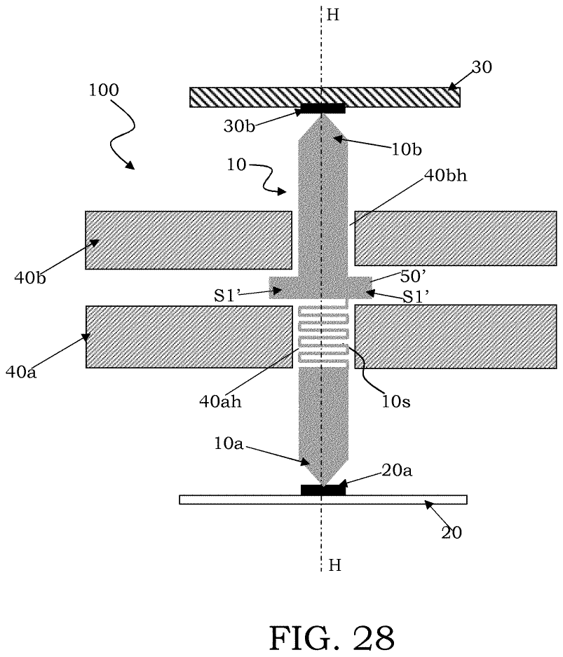

Referring now to FIG. 28, the guide 40 can comprise a first guide 40a, comprising respective first guide holes 40ah, and a second guide 40b associated with the first guide 40a and comprising respective second guide holes 40bh.

In an embodiment, the first guide 40a and the second guide 40b are arranged close, preferably in an intermediate area of the probe head 100 (between the semiconductor wafer 20 and the interface card 30), even if this is not necessary.

In other words, in this embodiment, the probe head 100 comprises the first guide 40a and the second guide 40b, which are preferably two intermediate guides.

The elastically compliant intermediate section 10s is arranged at one of the first guide hole 40ah and the second guide hole 40bh (in the example of FIG. 28 the elastically compliant intermediate section 10s is arranged at the first lower guide hole 40ah, even if the present invention is not certainly limited to this specific configuration).

Suitably, the contact probe 10 further comprises intermediate stop means arranged between the first guide 40a and the second guide 40b; these intermediate stop means are not limited by a particular type and can have various configurations (among which also the previously-discussed configurations represented in FIGS. 18 to 20), as it will be detailed below. In general, the intermediate stop means are configured to mechanically contact at least one portion of the first guide 40a and/or of the second guide 40b for the retention of the contact probe 10 inside the probe head 100, in particular to prevent the slipping thereof outside the first and/or second guide holes, for instance when the device under test and/or the PCB is not present.

For instance, as illustrated in FIG. 28, the intermediate stop means comprise an intermediate stopper (identified here with the reference 50′), which can have the same configuration as the stopper 50 discussed with reference to FIG. 18 (it can project from two walls or even from a single wall or in general any suitable configuration). The intermediate stopper 50′ has thus a transversal extension such as to define at least one shoulder (in particular two shoulders S1′ and S2′) configured to abut onto a face of the first guide 40a and/or of the second guide 40b, and thus defining an abutment surface for abutting onto said faces (as previously seen, on the whole, the stopper 50′ joined to the probe body portion can have a transversal extension which is greater than the one of the guide hole for a suitable retention of the contact probe).

The presence of the intermediate stopper 50′ thus ensures that the contact probe 10 is suitably retained in the probe head 100, in particular the combination of the intermediate stopper 50′ with the first guide 40a and the second guide 40b prevents the contact probe from exiting in both directions, and thus when the semiconductor wafer 20 is not present and at the same time the interface card 30 is not present, causing the retention of the short contact probe 10 in a simple way.

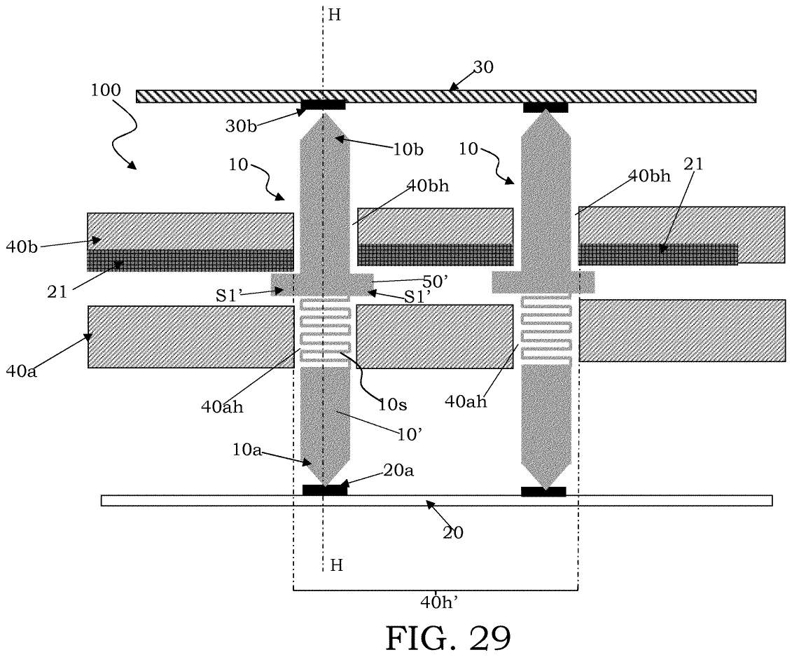

As illustrated in FIG. 29, in an embodiment of the present invention, the intermediate stopper 50′ can be configured to abut onto the conductive portion 21 formed on a face of the first guide 40a or of the second guide 40b, making an electrical connection with said conductive portion 21 and thus allowing to short-circuit the contact probe 10 inside the corresponding domain. In the example of FIG. 29, the intermediate stopper 50′ abuts through the shoulders S1′ and S2′ thereof onto the lower face of the second upper guide 40b, in which the conductive portion 21 is present, even if the conductive portion 21 can be formed at the first lower guide 40a, which the intermediate stopper 50′ is able to abut onto. In general, the conductive portion 21 can be formed on a face FA and/or FB of the first guide 40a and/or of the second guide 40b, as well as in any suitable way (even embedded in said guides). Furthermore, a plurality of conductive portions corresponding to a plurality of conductive domains can be provided, said conductive portions being arranged on a same face of the first guide 40a and/or of the second guide 40b, or on opposite faces of the first guide 40a and/or of the second guide 40b.

It is noted that FIG. 29 shows by mere way of example only two contact probes 10 short-circuited by the conductive portion 21, even if the present invention is not limited thereto and the group 40h′ can comprise any number of guide holes and thus of contact probes 10.

In the example of FIG. 29, the contact of the contact probe 10 with the conductive portion 21 is thus a pressing contact by means of one or more abutment surfaces of the at least one shoulder S1 and/or S2 of the intermediate stopper 50′, making in this way an electrical connection between the contact probe 10 and said conductive portion 21.

In general, it is noted that all was previously seen for the conductive portion 21 can also be applied to the present invention which provides a double intermediate guide, as well as it is possible to apply to this embodiment all the above-described geometries of the contact probes.

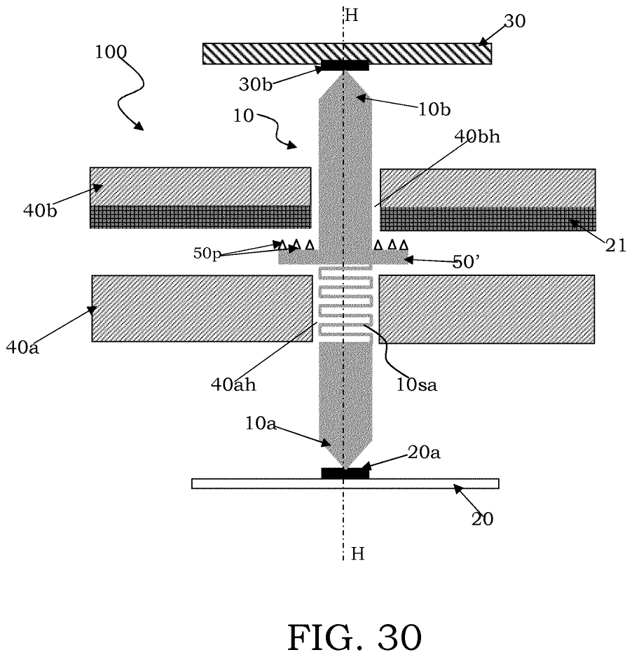

In order to increase the contact with the aforementioned metallization, and thus in order to increase the performances of the probe head 100, the intermediate stopper 50′ comprises a plurality of projections (identified here with the reference 50p) which protrude from at least one of the shoulders (i.e. they project from the abutment surface defined by said shoulder S1′ and/or S2′), as depicted in the example of FIG. 30. In particular, the projections 50p are adapted to contact part of the conductive portion 21, making an optimum electrical connection with said conductive portion 21.

Moreover, it is noted that the present invention is not limited by the particular shape of the projections 50p, which can for instance be triangular-tooth-shaped (as illustrated in FIG. 30), even if any suitable shape can be used; in an embodiment, the projections 50p can be generally defined by surface irregularities of the intermediate stopper 50′. Furthermore, these projections 50p can also project downwardly to abut onto the first guide 40a in addition or as an alternative to what shown in FIG. 30.

Moreover, it is noted that the presence of the projections 50p can also be envisaged in the case of a single guide, i.e. for instance in the case of FIG. 18 or 21A, with projections protruding downwardly to increase the quality of the contact with the guide, in particular with the metallization 21 formed on the upper face of the guide 40.

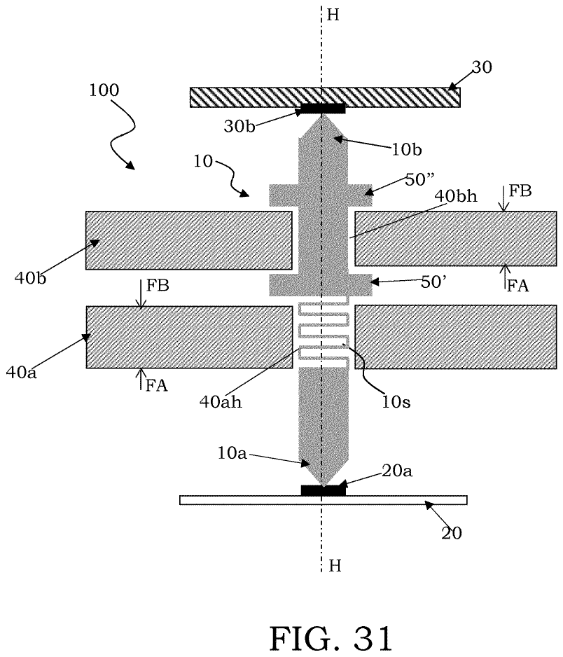

According to an embodiment illustrated in FIG. 31, the probe head 100 can also comprise a further stopper (here also called “upper stopper” and indicated with the reference 50″), which is arranged to abut onto an upper face FB of the second guide 40b, which is the face being furthest from the device under test. In other words, the upper stopper 50″ acts as a cap for a still more effective retention of the contact probe 10. The upper stopper 50″ can have the same shape and the same dimensions as the intermediate stopper 50′, but this is not strictly necessary.

Moreover, it is noted that, in this embodiment which envisages the presence of the first guide 40a and of the second guide 40b, the latter is fitted on the contact probe 10 after the probe has been housed in the first guide 40a.

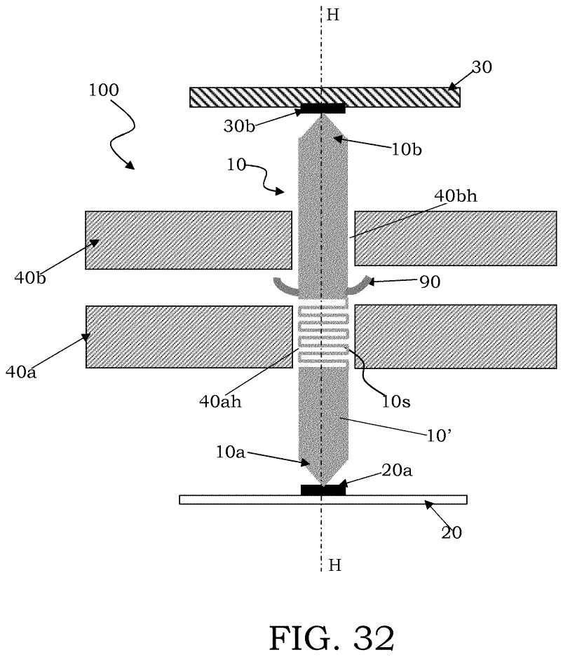

Furthermore, in order to facilitate the assembly of the probe head 100, instead of the intermediate stopper 50′ it is possible to provide a retention element shaped as an elastic hook (indicated in FIG. 32 with the reference 90). In particular, this elastic hook 90 is configured to elastically deform during the insertion of the contact probe 10, for instance when it is inserted from above through the second guide hole 40bh, as well as during the extraction of said contact probe 10 through the other guide hole, i.e. through the first lower guide hole 40ah (and thus with forced extraction from below).

Once the probe head 100 has been assembled, the elastic hook 90 is housed between the first guide 40a and the second guide 40b and is in a non-deformed configuration in which it is able to mechanically contact the first guide 40a and/or second guide 40b for the retention of said contact probe 10.

Advantageously, it is thereby possible to insert the contact probes 10 with the first guide 40a and the second guide 40b already assembled in the operating position thereof, while for the extraction of the contact probe 10 it is enough to pull the latter downwards through the first end 10a thereof, i.e. through the lower end thereof, considerably simplifying the assembly and the possible maintenance of the probe head.

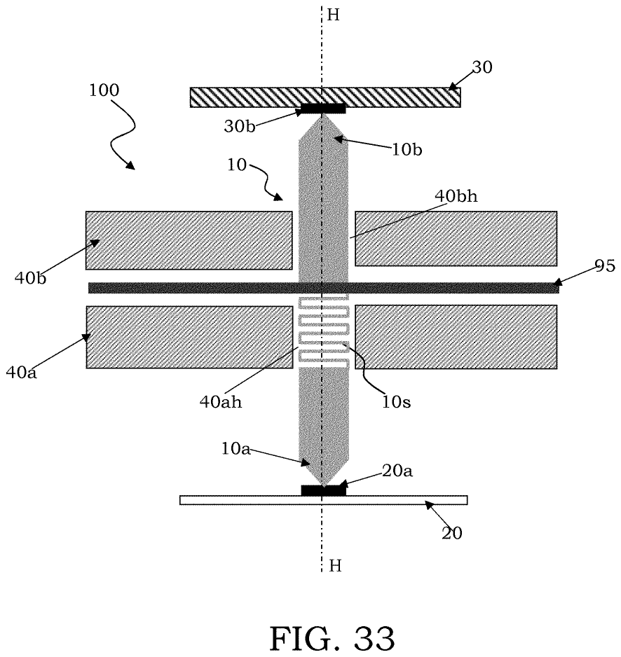

In accordance with a further embodiment of the present invention illustrated in FIG. 33, the intermediate stop means can comprise an elastic film (here indicated with the reference 95) arranged between the first guide 40a and the second guide 40b, for instance a Kapton sheet.

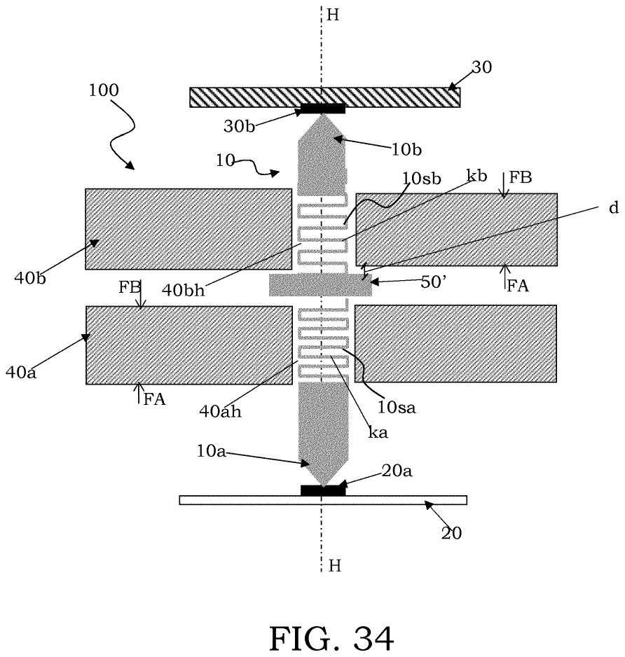

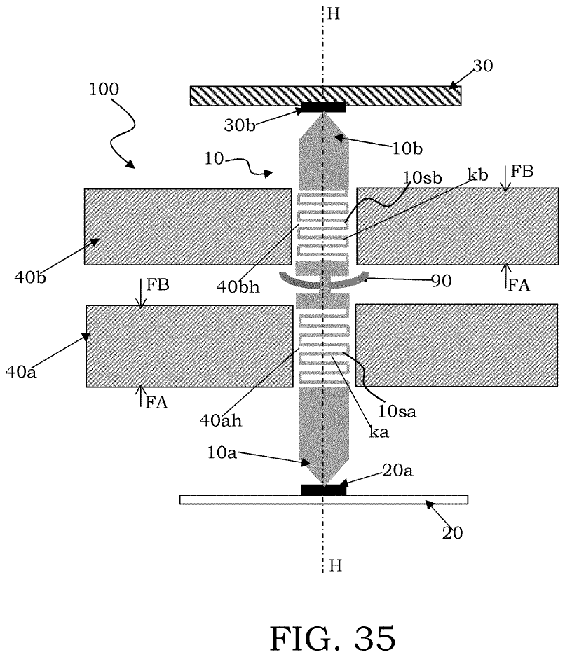

Referring now to FIG. 34, a particularly advantageous embodiment provides the presence of a first elastically compliant intermediate section 10san (also indicated for convenience as “first spring” or “lower spring”) at the first guide holes 40ah and a second elastically compliant intermediate section 10sb (also indicated for convenience as “second spring” or “lower spring”) at the second guide holes 40bh; the intermediate stop means (such as for instance the above intermediate stopper 50′—see FIG. 34—or also the aforementioned elastic hook 90 see FIG. 35) are arranged between the first elastically compliant intermediate section 10sa and the second elastically compliant intermediate section 10sb.

This embodiment has the advantage of enabling to control in an even finer way the movement (in particular the compression) of the contact probe 10, and thus in general there is an even more optimum definition and control of the contact force. For instance, it is thereby possible to control in an even finer way the movement in the vertical direction along the longitudinal axis H-H, even if, as previously seen, in this case too various geometries for the elastically compliant intermediate sections 10sa and 10sb are possible, with movements also in different directions.

The first elastically compliant intermediate section 10sa can have an elastic constant ka which is different from the elastic constant kb of the second elastically compliant intermediate section 10sb. In general, suitably, it is possible to suitably select these elastic constants.

Thereby, calling xa and xb the entities of the compressions which the first and the second springs are subjected to, the reaction force FR exerted by the contact probe 10 during the test (and thus during the compression thereof) is given by the known relationship FR=−ka·xa−kb·xb. By mere way of example, assuming an overdrive of 100 μm for the contact probe 10, it is possible to select the elastic constants ka and kb so that the first spring 10sa has a compression of 70 μm while the second spring 10sb has a compression of 30 μm, i.e. in this case the first spring 10sa has an elastic constant ka which is greater than the elastic constant kb of the second spring 10sb. Moreover, assuming a distance d which is equal to a 30 μm between the intermediate stopper 50′ and the lower face FA of the second guide 40b, it is ensured for certain that the intermediate stopper 50′ abuts onto the lower face FA.

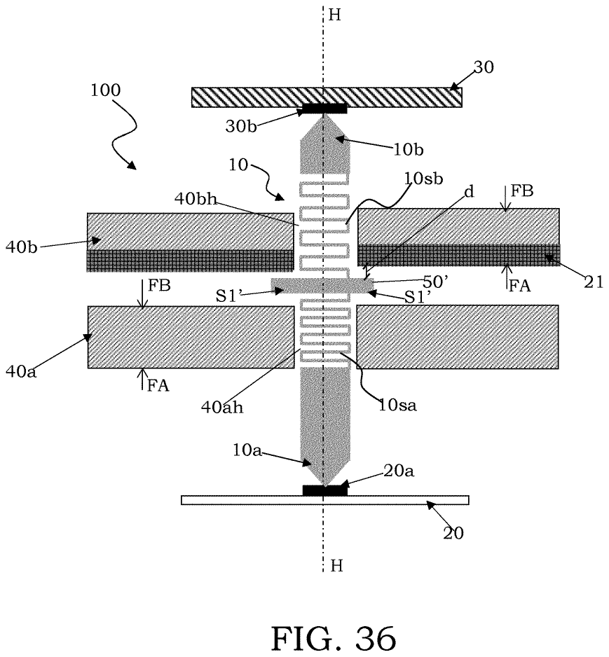

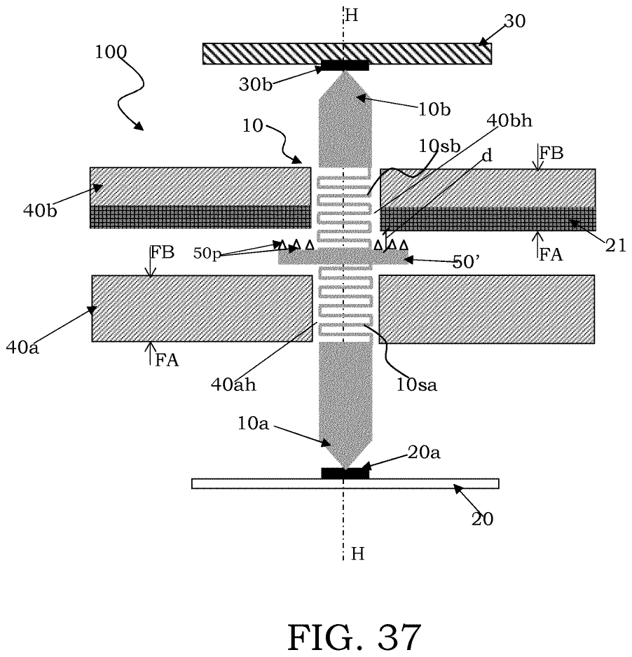

All of this is advantageous particularly when groups of probes are to be short-circuited with each other by the conductive portion 21 (see FIG. 36 for this purpose), since the pressing contact on the conductive portion 21 is always ensured by adjusting the elastic constants of the springs (and thus selecting for instance the guide to abut onto, the abutment being thereby ensured for certain and with a proper contact force). As previously seen, this contact can be further improved by the presence of the projections 50p, as illustrated in FIG. 37.

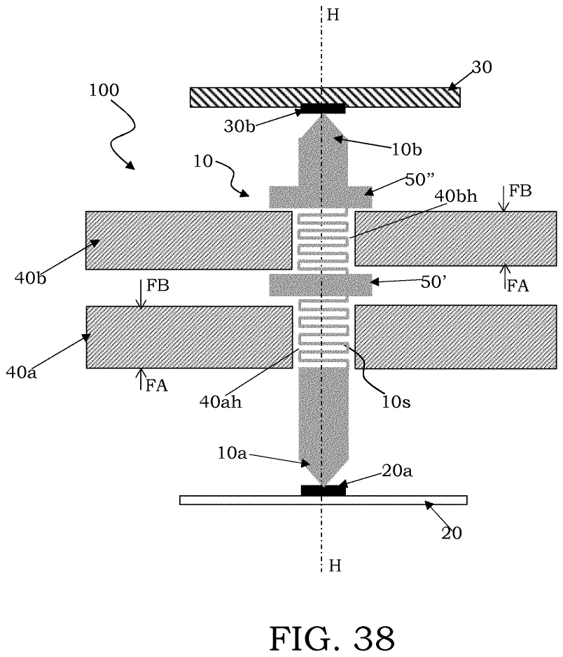

Obviously, it is possible to combine the various above-illustrated embodiments, such as for instance to also provide the presence of an upper stopper 50″ (as illustrated in FIG. 38), possibly in the presence of one or more conductive portions 21.

Furthermore, in an embodiment not illustrated in the figures, the first guide 40a and the second guide 40b can be shifted from each other with respect to the longitudinal axis H-H (i.e. the respective holes are not aligned with each other along said vertical reference axis) further favouring the (sliding) contact with the walls of the guide hole 40h.

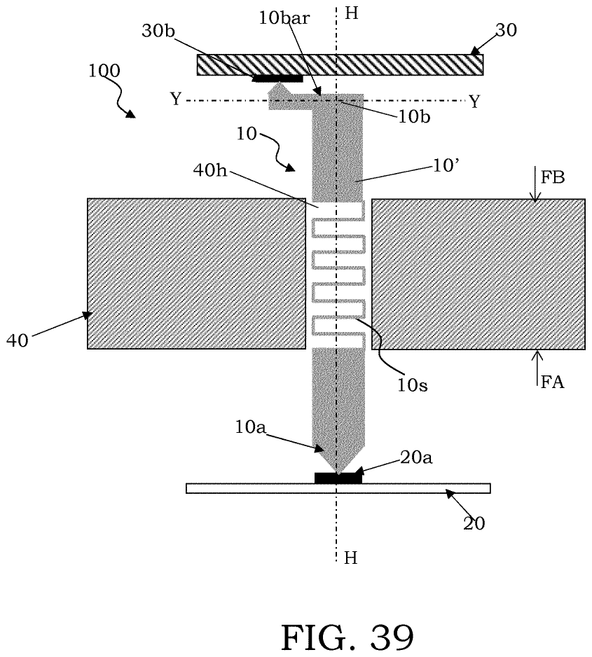

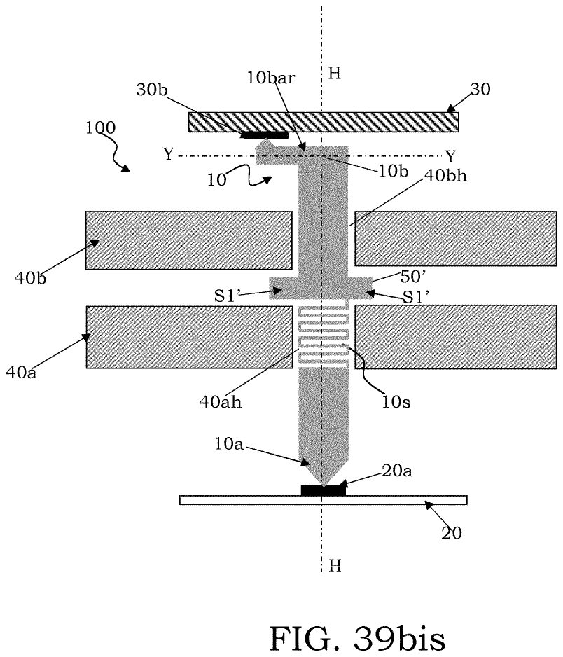

Referring now to the embodiment illustrated in FIG. 39, the second end 10b of the contact probe 10 can be structured so as to comprise an arm 10bar laterally protruding from the probe body 10′ and configured to perform the contact with the contact pads 30b of the interface card 30. The projecting arm 10bar is thereby adapted to offset the contact point between the contact probe 10 and the contact pad 30b of the interface card 30 with respect to the longitudinal axis H-H of the contact probes 10.

In the example of FIG. 39, the arm 10bar extends along an axis Y-Y which is substantially orthogonal to the longitudinal axis Y-Y, even if this is not strictly necessary.

This embodiment has the advantage that the contact pads formed on the interface card 30 are spatially redistributed compared to the ones of the device under test due to the shape of the contact probes 10 themselves, equipped with the arms 10bar projecting from the probe body 10′, without using a space transformer interposed between the probes and the PCB. It is thus possible not to arrange an interposer between the PCB and the probe head 100, so that in this embodiment the interface card 30 is just a PCB.

Furthermore, in an embodiment not illustrated in the figures, the probe head 100 can comprise contact probes having arms 10bar between each other which have a different length to obtain an even more effective spatial redistribution of the contact pads 30b on the PCB 30 compared to the ones of the device under test, the length of said arms 10bar being measured along the longitudinal development direction Y-Y thereof. Due to the presence of the arms having a different length, it is thus possible to vary the pitch of the pads 30b on the PCB compared to the pitch of the pads 20a on the device under test, in particular it is possible to relax the distance constraints between the centres of the contact pads on the PCB compared to the ones of the device under test. The length and the arrangement of the arms 10bar, which can vary from one probe to another one, are selected based on the specific requirements, and contact probes not equipped with arms are also possibly present, so as to obtain a particularly effective configuration.

This embodiment is particularly advantageous in the case of large-sized probe heads, such as for instance those used in the testing of storage devices such as DRAMs, since the architecture illustrated herein allows to use a smaller number of components. In particular, it is possible to avoid the presence of space transformers between the PCB and the probe head such as MLC (acronym for “Multi Layer Ceramic”) or MLO (acronym for “Multi Layer Organic”), having a high complexity, a high cost and very long supply times. Furthermore, it is possible to interface the probe head with a PCB having a simpler and thus also cheaper structure, having a relaxed pitch (for instance with greater relative distances—and thus a lower density—compared to the device under test and/or with a configuration selected in a simple way based on the needs).

In the example of FIG. 39, the actual contact with the pads 30b of the PCB 30 is made by a contact element formed on the upper surface of the arm 10bar, for instance at a free end thereof. This contact element however does not necessarily display a pointed shape and can have also other shapes compared to the one indicated in the figure.

Obviously, the embodiment of FIG. 39 can also be combined with the other ones, and thus for instance it is possible to provide also one or more of a stopper, a pre-load elastic portion between the stopper and the arm 10bar, the contact with conductive portions, and many other configurations, or a double guide and intermediate stop elements (as in FIG. 39bis).

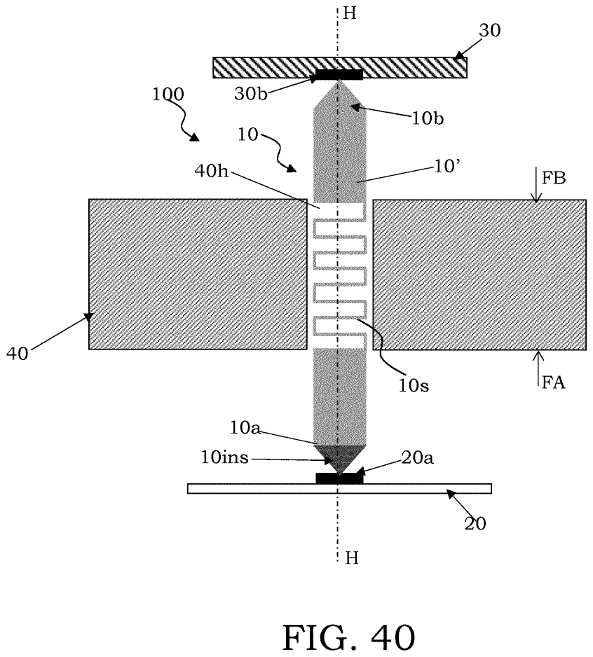

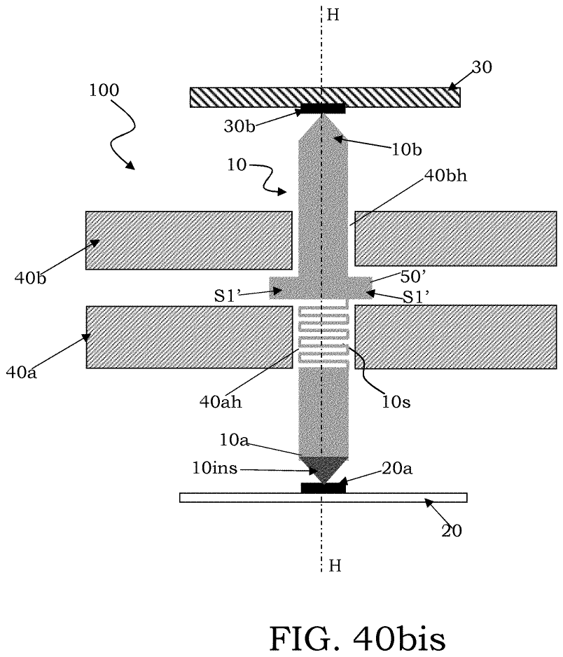

Referring now to the embodiment of FIG. 40, the first end 10a of the contact probe 10 (i.e. the lower end) can comprise a high-hardness material 10ins, in particular with a higher hardness compared to the material of the probe body 10′, such as rhodium for instance, even if other materials can be used.

Obviously, FIG. 40, in which the high-hardness material makes the entire terminal section of the contact probe 10, is provided only by way of example and other configurations can be provided, where in general the high-hardness material 10ins can be adapted to perform the contact with the pads 20a of the device under test and it is thus such as to ensure a contact tip at least partially having a high hardness. For instance, in an embodiment, the high-hardness material 10ins can be an insert supported by a complementary section of the probe body 10′ and intended to contact the pads 20a of the device under test, or it can be a coating of the first lower end 10a, or a layer of material, or any suitable configuration. In other cases, the tip can be made by layers of which the high-hardness material is the core.

This embodiment of FIG. 40 ensures a high service life of the contact probe 10, while keeping a high-quality contact.

This embodiment can also be combined with all the above-described embodiments since they concern the first end 10a of the contact probe; FIG. 40bis shows the combination with the double guide and the intermediate stop means.

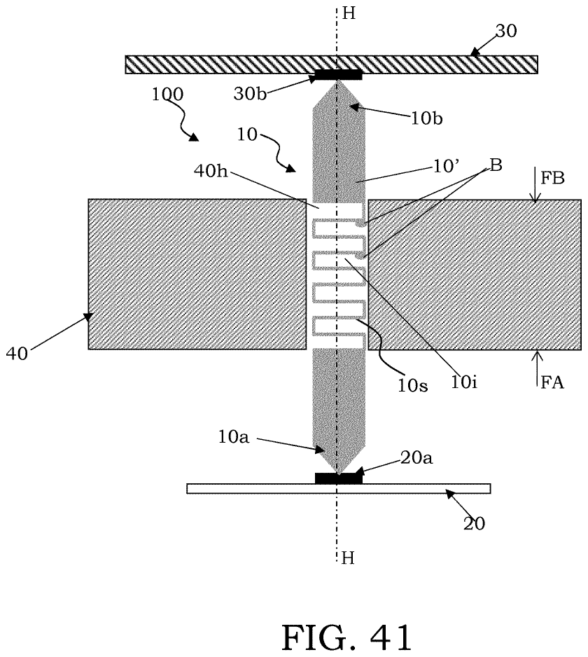

Finally, referring to the embodiment of FIG. 41, it is noted that the presence of the elastically compliant intermediate section 10s, characterized by several loops (and more generally by the succession of various elastic elements or portions or elastic sub-sections composing this elastic section 10s, as described in the previous examples), increases the actual length of the contact probe 10; in order to solve this problem, the elastically compliant intermediate section 10s comprises, at at least one of the elastic elements thereof, at least one projecting element or bump (reference B) configured to contact, during the testing of the device under test (i.e. when the elastic section 10s compresses), an adjacent elastic element, causing an electrical connection between said elastic elements which reduces the actual length of said elastically compliant intermediate section 10s and improves the performances of the probe head 100 (in fact a shorter path for the current is formed).

As a result, in this embodiment, at least one of the elastic elements of the elastically compliant intermediate section 10s (which is split in a plurality of elastic elements which follow each other without interruption-as previously seen) comprises a projecting element B protruding towards an adjacent elastic element and configured to contact a portion of said adjacent elastic element during the testing of the electronic device, said portion being separated from said projecting element B under rest conditions (i.e. when the elastic section is not compressed).

In other words, in this embodiment, the elastically compliant intermediate section 10s comprises the projecting element B configured to cause the electrical contact between portions of said elastically compliant intermediate section 10s which otherwise would be separated.

The projecting element B can be formed integral with the elastically compliant intermediate section 10s, without the present invention being limited by a manufacturing method.

For instance, the projecting element B can be formed at an edge or loop of the respective elastic element, even if other configurations are possible.

It is also possible to provide a plurality of projecting elements B, whose number is selected based on the selected length in compression of the elastically compliant intermediate section 10s, i.e. based on the length to be obtained; the more projecting elements B are present, the greater is the length of the elastic section in compression, for which reason it is preferable to keep a limited number of said projecting elements B.

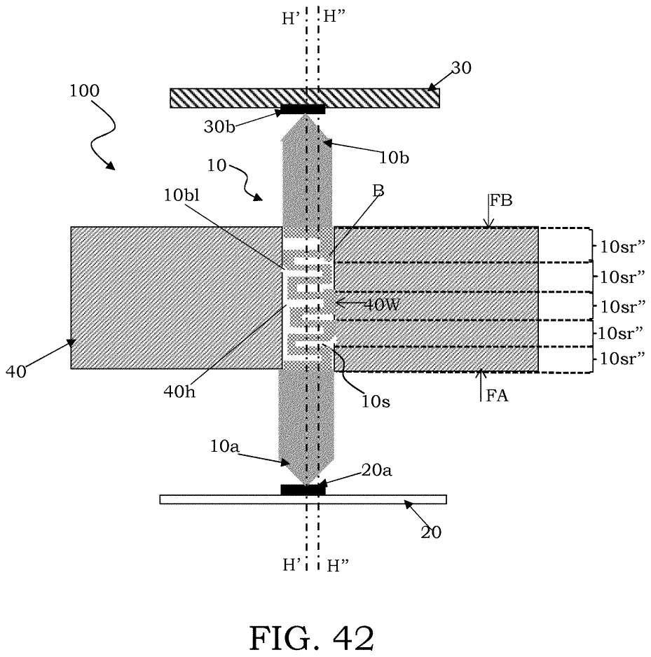

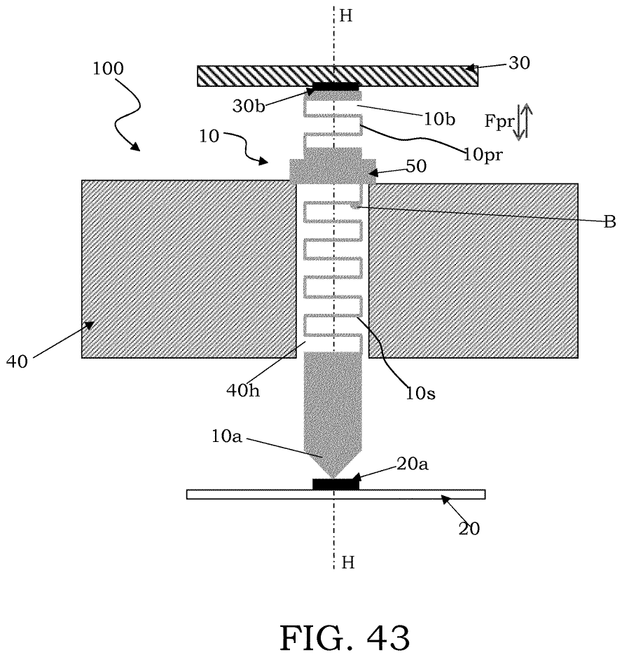

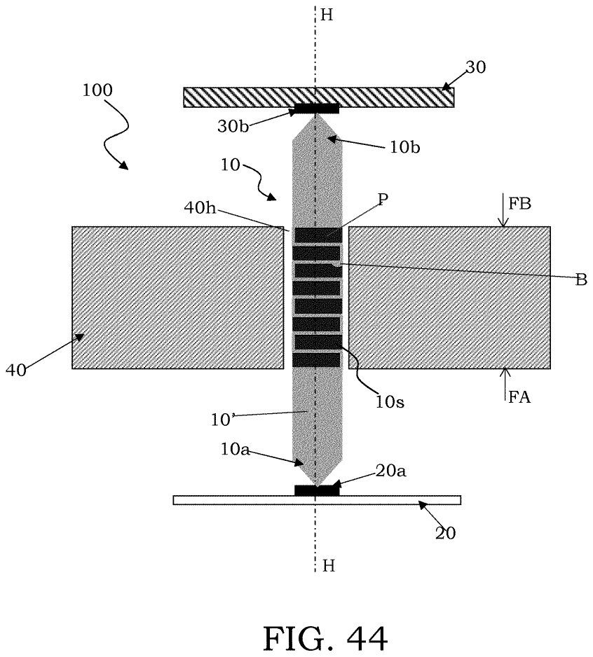

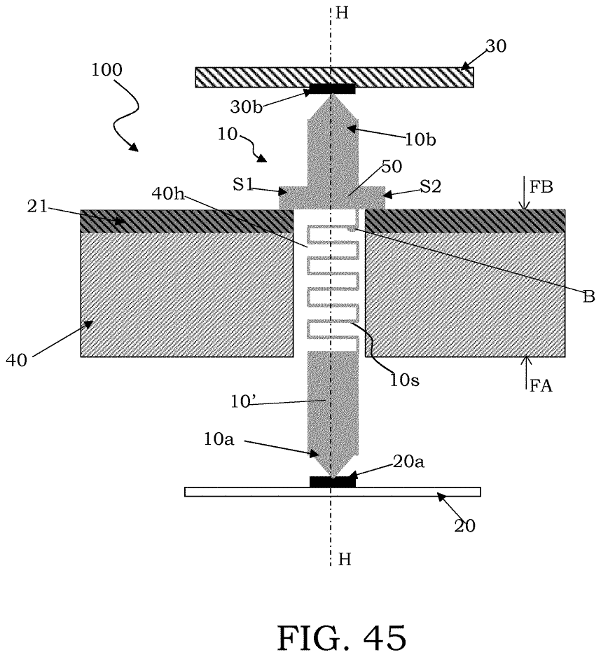

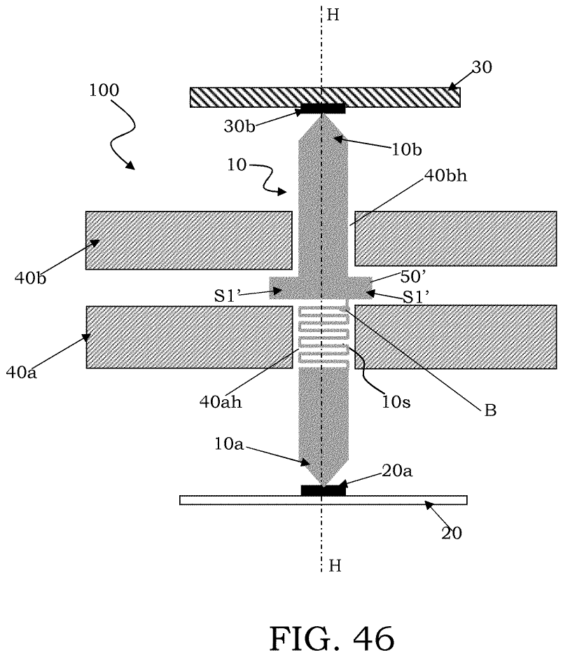

This embodiment of FIG. 41 is applicable to all the geometries previously seen for the elastically compliant intermediate section 10s or to the various configurations of the guide and of the holes, even if for simplicity FIG. 41 only shows a step-like sectional shape for the elastically compliant intermediate section 10s. FIGS. 42 to 46 are examples of a combination of the bumps B according to this embodiment with a non-rectilinear elastically compliant intermediate section, with the presence of a pre-load elastic portion, with the presence of the polymeric material P, with the presence of the conductive portion 21 (with a further increase in the frequency performances—in this case the figure only shows one of the many possible configurations and the stopper can be absent), and with a double guide and intermediate stop means respectively.

Summarizing the above, in conclusion, the present invention thus allows to successfully overcome the technical problem, providing the above probe head (which comprises very short contact probes acting as elastic springs) and solving all the drawbacks of the prior art in a simple way.

Advantageously according to the present invention, it is possible to effectively control the intensity of the contact force and more generally the compression of the contact probes, suitably shaping and sizing the elastically compliant intermediate section. Similarly, starting from a given configuration of the elastically compliant intermediate section, it is however possible to adjust the intensity of the contact force by varying the probe overtravel.

In general, whatever the manufacturing method is (for instance removal of some material from the body, locally reducing the rigidity thereof), a reduced-rigidity elastic section is obtained, said elastic section being formed by elastic elements which follow each other and represent the fundamental units thereof.

The reduced length of the contact probes, which can thus be seen as micro-springs, makes the probe head of the present invention suited to test high-frequency devices, while solving the problem of the rigidity of the short probes of the known solutions.

Moreover, the above-described particular configurations allow to ensure a proper stability of the contact probes and to avoid a deformation thereof during the test, as well as they allow the proper retention thereof and a simple assembly.

Unlike the vertical probe heads manufactured according to the prior art, the probe head according to some embodiments further allows to use a single guide, the contact probes deforming inside the guide hole. The use of a single guide simplifies the operations of assembling the probe head and is economically more advantageous, while the use of two guides allows to extend the elastic section.

Configurations are then possible, which provide a first and a second intermediate guide, for instance for an even more effective retention of the contact probe and a greater flexibility in the selection of the various possible configurations (with intermediate stop means and advantageous configurations). The presence of a double guide, intermediate stop means and one (preferably two) elastic section in the respective hole further helps to ensure the suitable pre-load of the contact probe.

Different geometries for the elastic section and different directions and types of deformation, not necessarily exclusively longitudinal, can be provided. For instance, besides spiral springs and symmetrical springs with a step-like section, other shapes (also asymmetrical and with lateral deformations) are also possible.

Furthermore, the presence of a pre-load spring ensures a proper contact in every situation, regardless of the manufacturing tolerances of the probe head.

Furthermore, the use of conductive portions contacted by portions of the short probe ensures high performances.

Moreover, the probe head according to the invention has, due to the advantageous shape thereof, a limited consumption of the contact pads.

Moreover, the presence of the polymeric material allows to increase the elastic response of the elastically compliant intermediate section itself and to ensure a greater strength to the lateral deformation, with improved elastic and mechanical properties.

Moreover, the presence of the bumps ensures high frequency performances, reducing the actual length of the elastic section.

Finally, it is noted that all the above embodiments can be combined with each other, even when the combination is not expressly illustrated or described; for instance, it is possible to combine two or more of the following advantageous configurations: a particular shape of the turns, a particular non-rectilinear shape of the elastically compliant intermediate section, or a particular arrangement of the metallizations, or the presence of the pre-load elastic portion and of the stop means, or the presence of a polymeric material in which the spring is embedded, or the presence of a double intermediate guide, or the presence of bumps or projecting elements, or various shapes for the stop means, or the presence of the protruding arms, or the presence of a tip made of a high-hardness material, or even with any configuration suited to the various applications.

Although most of the figures show, not to burden the description, an elastically compliant intermediate section with a step-like section, the various embodiments (for instance the configuration of the guide/s, the presence of the pre-load elastic portion, various configurations of the holes or of the stop means, and so on) can also be applied to the other described geometries.

Obviously, in order to meet contingent and specific requirements, a person skilled in the art can bring to the above-described probe head several modifications and variants, all falling within the scope of protection of the invention as defined by the following claims.

1. A probe head for the testing of electronic devices, comprising:
at least one contact probe comprising a body which extends along a longitudinal axis between a first end and a second end, said ends being adapted to contact respective contact pads; and
at least one guide comprising at least one guide hole configured for housing at least one portion of the contact probe,
wherein the contact probe comprises at least one intermediate section arranged between the first end and the second end which is elastically compliant at least along said longitudinal axis, and
wherein the elastically compliant intermediate section is configured to define an intensity and/or direction of a contact force exerted by the contact probe onto the contact pads, said contact probe acting as a spring.

2. The probe head according to claim 1, wherein the contact probe has a length which is lower than 2000 μm, preferably lower than 1000 μm, still more preferably equal to or lower than 800 μm, said length being measured along the longitudinal axis.

3. The probe head according to claim 1, wherein the guide comprises a first guide portion and a second guide portion, said second guide portion being initially made structurally independent from said first guide portion and being subsequently associated therewith.

4. The probe head according to claim 3, wherein the second guide portion is superimposed to the first guide portion and is fitted on the contact probe, and/or wherein the second guide portion is connected to the first guide portion by attachment means.

5. The probe head according to claim 1, wherein the elastically compliant intermediate section is obtained by interdigitated engravings formed in the body of the contact probe, said interdigitated engravings being configured so that the contact probe acts as an elastic spring.

6. The probe head according to claim 1, wherein the elastically compliant intermediate section is sawtooth-shaped, or it is structured as a plurality of polygonal elastic elements which follow each other along the longitudinal axis, such as for instance a succession of interconnected hexagons.

7. The probe head according to claim 1, wherein the elastically compliant intermediate section is structured as a plurality of oblong-shaped elastic elements which follow each other along the longitudinal axis of the contact probe.

8. (canceled)

9. The probe head according to claim 1, wherein the contact probe comprises a plurality of elastically compliant intermediate sections separated from each other by portions of the body of said contact probe, said elastically compliant intermediate sections following each other along the longitudinal axis.

10. The probe head according to claim 1, wherein the elastically compliant intermediate section is positioned at the guide so as to be at least partially accommodated in the guide hole.

11. The probe head according to claim 1, comprising a lower guide and an upper guide separated from each other by a gap, said lower guide and said upper guide comprising respective lower guide holes and upper guide holes for housing the contact probes wherein the elastically compliant intermediate section is placed at the gap between the lower guide and the upper guide.

12. (canceled)

13. The probe head according to claim 11, wherein the lower guide holes and the upper guide holes are unaligned with respect to each other.

14. The probe head according to claim 1, wherein the elastically compliant intermediate section extends along the longitudinal axis by a length of 1000 μm to 80 μm, and with a pitch of 100 μm to 5 μm.

15. (canceled)

16. The probe head according to claim 1, wherein at least one guide hole comprises at least one wall which is tilted with respect to the longitudinal axis, said guide hole having a non-rectilinear sectional shape.

17. (canceled)

18. The probe head according to claim 1, wherein the elastically compliant intermediate section is configured so that the contact force exerted by the contact probe onto the contact pads is substantially directed along the longitudinal axis, with substantially null transversal component, or wherein said contact force has also a component along an axis which is different from said longitudinal axis, for instance a transversal one.

19. The probe head according to claim 1, wherein the second end of the contact probe comprises an arm which laterally protrudes from the body thereof and is configured to perform the contact with the contact pads of an interface card, said arm being adapted to offset the contact point between the contact probe and the contact pad of the interface card with respect to the longitudinal axis of the contact probe, said probe head comprising a plurality of contact probes having arms between each other which have a different length, the length of said arms being measured along a longitudinal development direction thereof.

20. (canceled)

21. The probe head according to claim 1, wherein the first end of the contact probe comprises a high-hardness material, such as rhodium for instance.

22. The probe head according to claim 1, further comprising a conductive portion formed on the guide, said conductive portion including at least one group of said guide holes and being adapted to contact and short-circuit a corresponding group of contact probes which are housed in said group of holes and intended to carry a given kind of signal, thereby forming a given conductive domain, wherein at least one portion of the contact probe is in contact with said conductive portion.

23. The probe head according to claim 1, wherein the elastically compliant intermediate section is structured as a plurality of interconnected elastic elements which follow each other along the longitudinal axis of the contact probe, each of said elastic elements being configured to be compressed under the action of the pressure generated during the testing of the device under test, and being configured to be subjected, during said compression, to a reduction in its dimensions along said longitudinal axis of the contact probe and to an increase in its transversal dimensions, said elastic elements having an elongated shape along the longitudinal axis.

24. The probe head according to claim 22, further comprising a conductive portion formed on the guide, said conductive portion including at least one group of said guide holes and being adapted to contact and short-circuit a corresponding group of contact probes which are housed in said group of holes and intended to carry a given kind of signal, thereby forming a given conductive domain, wherein at least one portion of the contact probe is in contact with said conductive portion, wherein at least one of said elastic elements configured to contact, through a side wall thereof, the conductive portion following the increase in the transversal dimensions thereof during the testing of the device under test.

25. The probe head according to claim 1, wherein the contact probe comprises stop means formed on the body thereof and configured to mechanically contact at least one portion of the guide so as to cause the retention of said contact probe inside the probe head, wherein the stop means comprise a stopper having a transversal extension such as to define at least one shoulder configured to abut onto a face of the guide, said face being opposite a face of the guide facing towards the device under test, and/or wherein the stop means comprise at least one clip configured to mechanically interfere with the guide hole and to contact a corresponding wall of said guide hole, said clip projecting from the body of the contact probe and being configured to elastically deform during the contact with the wall of the guide hole, thereby causing the retention of the contact probe by mechanical interference with said guide hole.

26. (canceled)

27. The probe head according to claim 26, wherein the contact probe comprises an elastic portion arranged between the stop means, in particular the stopper, and the second end thereof, said elastic portion being configured to be pre-compressed under rest conditions after the assembly of the probe head and to exert, once pre-compressed, a pre-load force at least along the longitudinal axis.

28. The probe head according to claim 1, wherein the elastically compliant intermediate section is embedded in a polymeric material.

29. The probe head according to claim 1, wherein the guide comprises a first guide comprising respective first guide holes, and a second guide comprising respective second guide holes, wherein the elastically compliant intermediate section is arranged at at least one of said first guide holes and second guide holes, and wherein the contact probe further comprises intermediate stop means arranged between said first guide and said second guide, said intermediate stop means being configured to mechanically contact at least one portion of said first guide and/or said second guide for the retention of the contact probe inside the probe head.

30. The probe head according to claim 29, wherein the intermediate stop means comprise an intermediate stopper having a transversal extension such as to define at least one shoulder configured to abut onto a face of the first guide and/or of the second guide, or wherein the intermediate stop means comprise a retention element shaped as an elastic hook, which is configured to elastically deform during the insertion of the contact probe through one of the first guide hole or the second guide hole and during the extraction of said contact probe through the other one of said first guide hole and second guide hole, said retention element, when housed between the first guide and the second guide, being in a non-deformed configuration and being adapted to contact the first guide and/or the second guide for the retention of said contact probe.

31. (canceled)
